(19) United States
(12) Patent Application Publication
(10) Pub. No.: US 2022/0342640 A1
(43) Pub. Date: Oct. 27, 2022

(54) SEMICONDUCTOR ELEMENT, NONVOLATILE MEMORY DEVICE, MULTIPLY-ACCUMULATE OPERATION DEVICE, AND METHOD OF MANUFACTURING SEMICONDUCTOR ELEMENT

(71) Applicants: SONY SEMICONDUCTOR SOLUTIONS CORPORATION, KANAGAWA (JP); SONY GROUP CORPORATION, TOKYO (JP)

(72) Inventors: MASANORI TSUKAMOTO, TOKYO (JP); TOSHIYUKI KOBAYASH, KANAGAWA (JP)

(21) Appl. No.: 17/754,029

(22) PCT Filed: Aug. 13, 2020
(86) PCT No.: PCT/JP2020/030750

§ 371 Date: Mar. 22, 2022

(30) Foreign Application Priority Data
Sep. 30, 2019 (JP) 2019-178928

(51) Int. Cl. G06F 7/544; G11C 11/22; H01L 27/1159; H01L 27/11597

(52) U.S. Cl. CPC G06F 7/5443; G11C 11/223; H01L 27/1159; H01L 27/11597

(57) ABSTRACT

[Object] To provide a semiconductor element capable of realizing an element having a nonvolatile memory capable of stably storing highly integrated data, a nonvolatile memory device, a multiply-accumulate operation device, and a method of manufacturing the semiconductor element. [Solving means] A semiconductor element according to an embodiment of the present technology includes a plurality of cell blocks. The plurality of cell blocks are configured by connecting a plurality of cell portions in series with each other, the plurality of cell portions each having a MOSFET for controlling conduction of a channel portion and a resistor connected in parallel to the channel portion, and configured to store data by a resistance level set for each of the plurality of cell portions.

### CROSS REFERENCE TO RELATED APPLICATIONS

This application claims the benefit of Japanese Priority Patent Application JP 2019-178928 filed Sep. 30, 2019, the entire contents of which are incorporated herein by reference.

### TECHNICAL FIELD

The present technology relates to a semiconductor element having a nonvolatile memory function, a nonvolatile memory device, a multiply-accumulate operation device, and a method of manufacturing the semiconductor element.

### BACKGROUND ART

Conventionally, an element having a nonvolatile memory function has been known, and is used as a memory device for storing data or an operation device. In recent years, memory devices for storing multi-value data representing three or more values have been developed.

For example, Patent Literature 1 describes an FET-type memory cell using a ferroelectric film as a gate insulating film. In this memory cell, multi-value data is stored by accumulating different polarization amounts in the ferroelectric film. The multi-value data is read by detecting the potential between the channel of the memory cell and the weight element connected in series to the channel. Since the data stored in the element has a multi-value, it is possible to increase the storage capacity (paragraphs [0025], [0050], [0055], [0063], FIGS. 5 and 8, etc. of Patent Literature 1).

### CITATION LIST

### Patent Literature

### [PTL 1]

### Japanese Patent Application Laid-open No. 2009-295255

### SUMMARY

### Technical Problem

However, in the method as disclosed in Patent Literature 1, it becomes difficult to control the polarization-state as the cell is miniaturized, and there is a possibility that the accuracy of writing and reading data is lowered. For this reason, there is a demand for a technique for realizing an element having a nonvolatile memory function capable of stably storing data and achieving high integration.

In view of the above circumstances, an object of the present technology is to provide a semiconductor element capable of realizing an element having a nonvolatile memory capable of stably storing highly integrated data, a nonvolatile memory device, a multiply-accumulate operation device, and a method of manufacturing the semiconductor element.

### Solution to Problem

In order to achieve the above object, a semiconductor element according to an embodiment of the present technology includes a plurality of cell blocks.

The plurality of cell blocks are configured by connecting a plurality of cell portions in series with each other, the plurality of cell portions each having a MOSFET for controlling conduction of a channel portion and a resistor connected in parallel to the channel portion, and configured to store data by a resistance level set for each of the plurality of cell portions.

In this semiconductor element, a cell portion is constituted by a resistor connected in parallel to a channel portion of a MOSFET, and a plurality of cell portions are connected in series with each other to constitute a cell block. Data is stored in the cell block according to the resistance level of each cell portion. This may realize an element having a nonvolatile memory function capable of stably storing highly integrated data.

The resistance level may be represented by a resistance value of the cell portion in a state where a predetermined voltage is applied to a gate of the MOSFET.

The MOSFET may include a nonvolatile memory layer, and may cause the channel portion to conduct according to a condition of the memory layer. In this case, the resistance level may be set according to a state of the memory layer.

The memory layer may be a gate dielectric film made of ferroelectric.

A threshold voltage of the MOSFET of each of the plurality of cell portions may be set to either a first value or a second value different from each other. In this case, the resistance level may be set by a threshold voltage of the MOSFET.

The cell block may include the plurality of cell portions formed on a same surface.

The resistor resistor may include a pair of electrode films and a resistor film sandwiched between the pair of electrode films. In this case, an area of the resistor film may be set to a different value for each of the plurality of cell portions included in the cell block.

The cell block may include the plurality of cell portions stacked on each other.

The MOSFET may include a cylindrical semi-conductive film extending along a stacking direction and on which the channel portion is formed. In this case, the resistor may include a resistor film formed to cover an inner surface and a bottom surface of the semiconductor film, and an electrode portion filled in a space surrounded by the resistor film.

A thickness of the resistor film may be set to a different value for each of the plurality of cell portions included in the cell block.

A resistance value of the resistor may be set to a different value for each of the plurality of cell portions included in the cell block.

The resistance value may be set to a value obtained by multiplying a predetermined value by an integer power of 2.

A resistance value of the resistor may be set to a same value for each of the plurality of cell portions included in the cell block.

The semiconductor element may further include: a plurality of source lines; a plurality of bit lines; and a plurality of word lines. In this case, the MOSFET may control conduction of the channel portion in accordance with a voltage of the corresponding word line. Further, each of the plurality of cell blocks may be a nonvolatile memory cell connected between the corresponding source line and the corresponding bit line, and configured to store data according to the resistance level set for each of the plurality of cell portions.

The semiconductor element may further include: a plurality of input lines in which an input signal representing an input value is input; a plurality of output lines; and a plurality of control lines. In this case, the MOSFET may control conduction of the channel portion in accordance with a voltage of the corresponding control line. Further, each of the plurality of cell blocks maybe a multiplier cell connected between the corresponding input line and the corresponding output line, and configured to store a weight value by the resistance level set for each of the plurality of cell portions, and generate a charge corresponding to a weight value obtained by multiplying the weight value and the input value, and constitutes a multiply-accumulate operation device by outputting a charge corresponding to the weight value to the common output line.

A nonvolatile memory device according to an embodiment of the present invention includes a plurality of source lines, a plurality of bit lines, a plurality of word lines, and a plurality of memory cells.

The plurality of memory cells are configured by connecting a plurality of cell portions in series between the corresponding source line and the corresponding bit line, the plurality of cell portions each having a MOSFET for controlling conduction of a channel portion in accordance with a voltage of the corresponding word line and a resistor connected in parallel to the channel portion, and configured to store data by a resistance level set for each of the plurality of cell portions.

The multiply-accumulate operation device according to an embodiment of the present technology includes a plurality of input lines, a plurality of output lines, a plurality of control lines, a plurality of multiplier cells, and a plurality of output units.

In the plurality of input lines, an input signal representing an input value is input.

The plurality of multiplier cells are configured by connecting a plurality of cell portions in series between the corresponding input line and the corresponding output line, the plurality of cell portions each having a MOSFET for controlling conduction of a channel portion in accordance with a voltage of the corresponding control line and a resistor connected in parallel to the channel portion, configured to store a weight value by a resistance level set for each of the plurality of cell portions, and configured to generate a charge corresponding to a weight value obtained by multiplying the weight value and the input value.

The plurality of output units are configured to output a multiply-accumulate signal representing a sum of the weight values in a group of the multiplier cells based on the charge output to the output line by the group of the multiplier cells connected to the common output line.

A method of manufacturing a semiconductor element according to an embodiment of the present technology is a method of manufacturing a semiconductor element including a plurality of cell blocks in which a plurality of cell portions are connected in series, including: a forming process of the plurality of cell portions including forming a MOSFET for controlling conduction of a channel portion, and forming a resistor connected in parallel to the channel portion.

The forming process of the MOSFET includes forming an element layer including a gate electrode film sandwiched between interlayer insulating films, forming a hole penetrating the element layer, and forming, on an inner surface of the hole, a gate dielectric film made of ferroelectric and a semiconductor film forming the channel portion, in this order.

The forming process of the resistor includes forming a resistor film so as to cover an inner surface and a bottom surface of the semiconductor film, and filling an electrode portion in a space surrounded by the resistor film.

### BRIEF DESCRIPTION OF DRAWINGS

FIG. 1 A circuit diagram showing a configuration example of a nonvolatile memory device according to a first embodiment of the present technology.

FIG. 2 A circuit diagram of a memory cell mounted in the nonvolatile memory device.

FIG. 3 A table showing an example of data stored in the memory cell.

FIG. 4 A table showing another example of data stored in the memory cell.

FIG. 5 A schematic sectional view showing a configuration example of a memory cell.

FIG. 6 A schematic sectional view showing a configuration example of a ferroelectric FET.

FIG. 7 A schematic sectional view showing a configuration example of a resistor.

FIG. 8 A plan view and a cross-sectional view showing each step of the method of manufacturing the nonvolatile memory device.

FIG. 9 A plan view and a cross-sectional view showing each step of the method of manufacturing the nonvolatile memory device.

FIG. 10 A plan view and a cross-sectional view showing each step of the method of manufacturing the nonvolatile memory device.

FIG. 11 A plan view and a cross-sectional view showing each step of the method of manufacturing the nonvolatile memory device.

FIG. 12 A plan view and a cross-sectional view showing each step of the method of manufacturing the nonvolatile memory device.

FIG. 13 A plan view and a cross-sectional view showing each step of the method of manufacturing the nonvolatile memory device.

FIG. 14 A plan view and a cross-sectional view showing each step of the method of manufacturing the nonvolatile memory device.

FIG. 15 A plan view and a cross-sectional view showing each step of the method of manufacturing the nonvolatile memory device.

FIG. 16 A schematic sectional view showing a configuration example of a memory cell mounted in the nonvolatile memory device according to the second embodiment.

FIG. 17 A schematic sectional view showing a configuration example of a partial cell.

FIG. 18 A plan view and a cross-sectional view showing each step of the method of manufacturing the nonvolatile memory device.

FIG. 19 A plan view and a cross-sectional view showing each step of the method of manufacturing the nonvolatile memory device.

FIG. 20 A plan view and a cross-sectional view showing each step of the method of manufacturing the nonvolatile memory device.

FIG. 21 A plan view and a cross-sectional view showing each step of the method of manufacturing the nonvolatile memory device.

FIG. 22 A circuit diagram showing a configuration example of a multiply-accumulate operation device according to the third embodiment.

### DESCRIPTION OF EMBODIMENTS

Embodiments according to the present technology will now be described below with reference to the drawings.

### First Embodiment

[Configuration of Nonvolatile Memory Device]

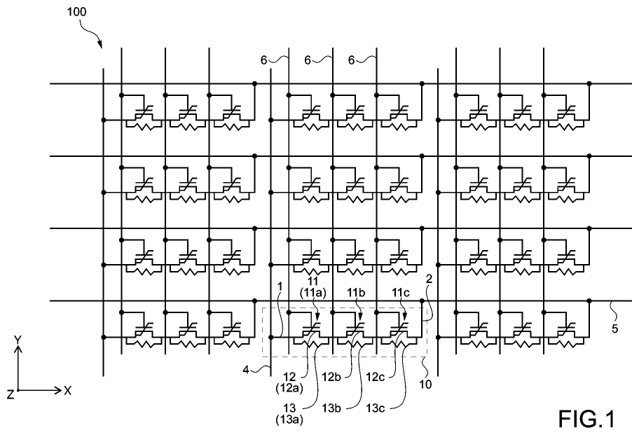

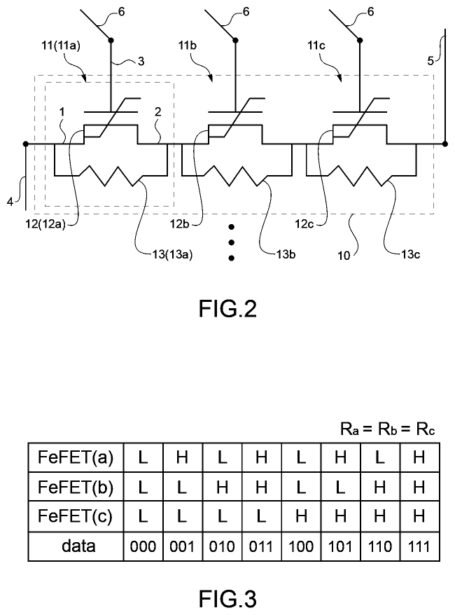

FIG. 1 is a circuit diagram showing a configuration example of a nonvolatile memory device 100 according to the first embodiment of the present technology. FIG. 2 is a circuit diagram of a memory cell mounted in the nonvolatile memory device 100. The nonvolatile memory device 100 is a nonvolatile semiconductor memory capable of maintaining recorded data even when power supply is stopped. In the present embodiment, the nonvolatile memory device 100 corresponds to a semiconductor element. In the present disclosure, a semiconductor element, for example, an integrated element in which a plurality of elements are integrated on a semiconductor board.

The nonvolatile memory device 100 has the plurality of memory cells 10. One memory cell 10 includes the plurality of partial cells 11. A memory cell 10 including the plurality of partial cells 11 is a basic unit in the nonvolatile memory device 100. As shown in FIG. 1, the nonvolatile memory device 100 is configured as a memory cell array in which the plurality of memory cells 10 are arranged vertically and horizontally in a matrix. In the nonvolatile memory device 100, data is stored by each partial cell 11 of the memory cell 10, and the stored data is read out. In the present embodiment, the plurality of memory cells 10 correspond to a plurality of cell blocks. The plurality of partial cells 11 included in each memory cell 10 corresponds to a plurality of cell portions.

As shown in FIGS. 1 and 2, in one memory cell 10, the plurality of partial cells 11 are connected in series. That is, the memory cell 10 has a chain cell structure in which the plurality of partial cells 11 are connected in a chain shape. By adopting a chain cell structure, wiring or the like connected to each partial cell 11 is reduced, it is possible to improve the degree of integration.

As shown in FIG. 2, the partial cell 11 has the ferroelectric FET 12 and the resistor 13. The ferroelectric FET 12 is an element of MOSFET (Metal Oxide Semiconductor Field Effect Transistor type using ferroelectrics for a gate dielectric film. The ferroelectric FET 12 has a source 1, a drain 2, and a gate 3. Between the source 1 and the drain 2, a channel portion serving as a conducting path (channel) is formed. The ferroelectric FET 12 may be controlled by switching between the conducting state and the non-conducting state of this channel portion. Hereinafter, a gate dielectric film made of ferroelectric is described as a ferroelectric film.

In the ferroelectric FET 12, the spontaneous polarization of the ferroelectric film may be controlled by an electric field between the gate 3 and the board or between the gate 3 and the source 1/the drain 2. Threshold voltage for controlling the conduction of the channel portion in response to the spontaneous polarization is set. Further, the ferroelectric FET 12 becomes a gain cell capable of amplifying the signal quantity that varies according to the polarization with MOSFET. Thus, it is possible to accurately adjust the intensity or the like of the signal passing through the channel portion.

The resistor 13 is a resistor having a predetermined resistance value, and has two terminals. The resistance value of the resistor 13 is typically set higher than the resistance value of the conductive state of the channel portion, and lower than the resistance value of the non-conductive state of the channel portion. The specific configuration of the ferroelectric FET 12 and the resistor 13 will be described in detail later. In this embodiment, the ferroelectric FET 12 is an example of MOSFET.

As shown in FIG. 2, the partial cell 11 has a 1T-1R structure in which one ferroelectric FET 12 (T) and one resistor 13 (R) are connected in parallel to each other. Specifically, one terminal of the resistor 13 is connected to the source 1 of the ferroelectric FET 12, and the other terminal of the resistor 13 is connected to the drain 2 of the ferroelectric FET 12. Therefore, the channel portion of the ferroelectric FET 12 and the resistor 13 are connected in parallel to each other, and thus the partial cell 11 is constituted.

The memory cell 10 is configured by connecting the plurality of partial cells 11 (1T-1R structure of the ferroelectric FET 12 and the resistor 13) in series. Thus, the memory cell 10 is configured by connecting the plurality of partial cells 11 having the ferroelectric FET 12 for controlling the conduction of the channel portion and the resistor 13 connected in parallel to the channel portion in series with each other. Specifically, the source 1 of one partial cell 11 of the adjacent partial cells 11 is connected to the drain 2 of the other partial cell 11. FIG. 2 shows a circuit in which three partial cells 11 a to 11c are connected in series as an example of the memory cell 10. The partial cell 11a includes the ferroelectric FET 12a and the resistor 13a, the partial cell 11b includes the ferroelectric FET 12b and the resistor 13b, and the partial cell 11c includes the ferroelectric FET 12c and the resistor 13c. In the memory cell 10 shown in FIG. 2, the ferroelectric FET 12a, the ferroelectric FET 12b, and the ferroelectric FET 12c are connected in series in this order. The ferroelectric FET 12a and the resistance 13a are connected in parallel, the ferroelectric FET 12b and the resistor 13b are connected in parallel, and the ferroelectric FET 12c and the resistor 13c are connected in parallel. The number of partial cells 11 included in the memory cell 10 is not limited. For example, the number of partial cells 11 may be appropriately set so that necessary data may be stored. Hereinafter, the number of partial cells 11 included in the memory cell 10 will be described as N. For example, FIG. 2 is an example of N=3.

As shown in FIG. 1, the nonvolatile memory device 100 includes the plurality of source lines 4, the plurality of bit lines 5, and a plurality of word lines 6. For example, one memory cell 10 is connected to one source line 4, one word line 6, and the same number of word lines 6 as the number of partial cells 11. The source line 4 is a wiring for supplying a source voltage to the memory cell 10, and also referred to as a plate line. The bit line 5 is a wiring for outputting data stored in the memory cell 10. The word line 6 is a wiring for selecting a memory cell 10 or a partial cell 11. In the example shown in FIG. 1, the plurality of source lines 4 and the plurality of bit lines 5 are arranged orthogonal to each other. The plurality of word lines 6 are arranged along a direction parallel to the source line 4.

Each of the plurality of memory cells 10 is connected between a corresponding source line 4 and a bit line 5. In FIGS. 1 and 2, the source line 4 corresponding to the source 1 of the ferroelectric FET 12a arranged at the left end of the memory cell 10 is connected, and the bit line 5 corresponding to the drain 2 of the ferroelectric FET 12c arranged at the right end is connected. The corresponding word lines 6 are connected to the respective gates 3 of the ferroelectric FETs 12a to 12c. In the nonvolatile memory device 100, the plurality of memory cells 10 are connected to these wirings, i.e., the source lines 4, the bit lines 5, and the word lines 6, thereby forming a memory cell array.

### [Basic Operation of Ferroelectric FET]

Here, the basic operation of the ferroelectric FET 12 will be described. A MOSFET is an element that controls the conduction of the channel portions. In a MOSFET, for example, in accordance with the voltage supplied to the gate (gate voltage Vg), it is possible to switch between the on-state in which the channel portion is in a conductive state and the off-state in which the channel portion is non-conductive state. In the ferroelectric FET 12 using the gate insulating film of a MOSFET as a ferroelectric film, the polarization-state is controlled between the state of applying a gate voltage in the positive direction (e.g., program state) and the state of applying a gate voltage in the negative direction (e.g., erase state), and it is possible to set a different threshold voltage Vt. In addition, the threshold does not fluctuate (nonvolatile) when the power is turned off. Thus, for example, when a predetermined voltage is applied to the word line 6 connected to the gate 3, on/off of the channel portion of the ferroelectric FET 12 having a different threshold may be switched. Thus the ferroelectric FET 12 is an element for controlling the conduction of the channel portion, the conduction of the channel portion is controlled in accordance with the voltage of the corresponding word line 6.

Here, the threshold voltage is a gate voltage Vg as a threshold value for switching the on-state and off-state of the ferroelectric FET 12 (conductive state and non-conductive state of the channel portion). For example, when the gate voltage Vg is smaller than the threshold voltage Vt, the ferroelectric FET 12 is turned off. In this case, the channel portion may be regarded as an insulating path having an insulating resistance. Further, for example, when the gate voltage Vg is equal to or greater than the threshold voltage Vt, the ferroelectric FET 12 is turned on. In this case, the channel portion may be regarded as a conducting path having a sufficiently low resistance.

In the present embodiment, for one ferroelectric FET 12, either of two types of threshold voltages that differ from each other is set. Among these two types of threshold voltages, a voltage whose value is higher is described as a high threshold voltage (HVt), and a voltage whose value is lower is described as a low threshold voltage (LVt). HVt and LVt may be set, for example, by reversing the direction of spontaneous polarization of the ferroelectric. Thus, the ferroelectric FET 12 conducts the channel portions according to the state of the ferroelectric film. The set threshold voltage is maintained even when the power of the nonvolatile memory device 100 is turned off. Therefore, the ferroelectric FET 12 functions as a nonvolatile memory device capable of freely setting either of HVt and LVt and storing the states of the memory device. In the present embodiment, the ferroelectric film corresponds to a nonvolatile memory layer.

For example, as the gate voltage Vg, the voltage set to a value between the HVt and LVt (read voltage Vr) is applied to the ferroelectric FET 12 (LVt<Vr<HVt). When Vr is applied to the ferroelectric FET 12 to which HVt is set, the ferroelectric FET 12 is turned off, and the channel portions become non-conductive. Further, when Vr is applied to the ferroelectric FET 12 in which LVt is set, the ferroelectric FET is turned on, the channel portion is in a conductive state. Thus, when the read voltage Vr is applied, the ferroelectric FET 12 controls the conduction of the channel portion so that the channel portion becomes one of the conductive state and the non-conductive state. In other words, the ferroelectric FET 12 is written with a two-valued threshold-voltage that causes the ferroelectric FET 12 to be in the on-state and off-state. In the present embodiment, the read voltage Vr corresponds to a predetermined voltage.

### [Basic Memory Cell Operation]

Next, the basic operation of the memory cell 10 is described. In the respective partial cells 11 constituting the memory cell 10, by utilizing the characteristics of the ferroelectric FET 12 described above, the resistance level is set. Here, the resistance level is, in a state where the read voltage Vr is applied to the gate of the ferroelectric FET 12, a level represented by the resistance value of the partial cell 11. Further, the resistance value of the partial cell 11 is the resistance value between the two connection terminals for connecting the partial cells 11 in series (e.g., source 1 and drain 2). Therefore, the resistance value of the partial cell 11 may be regarded as the resistance value of the parallel circuit between the channel portion and the resistor 13.

For example, when the read voltage Vr is applied to the ferroelectric FET 12 in which HVt is set, the partial cell 11 including the ferroelectric FET 12 is a state in which the non-conductive channel portion and the resistor 13 are connected in parallel. In this case, the resistor 13 having a relatively low resistance is selected as the main path of the current in the partial cell 11. Further, for example, when the read voltage Vr is applied to the ferroelectric FET 12 where LVt is set, the partial cell 11 including the ferroelectric FET 12 is a state in which the channel portion of the conductive state and the resistor 13 are connected in parallel. In this case, the channel portion (channel) of the relatively low resistance ferroelectric FET 12 is selected as the main path of current in the partial cell 11.

As described above, the resistance value of the resistor 13 is set higher than the resistance value of the channel portion of the conductive state and lower than the resistance value of the channel portion of the non-conductive state. Accordingly, the resistance level of the partial cell 11 including the ferroelectric FET 12 to which HVt is set becomes a level higher than the resistance level of the partial cell 11 including the ferroelectric FET 12 to which LVt is set. That is, two kinds of resistance levels may be set in each partial cell 11 by two kinds of threshold voltages HVt and LVt. For example, when the resistance level is high, 1 is set, and when the resistance level is low, 0 is set, so that data of 1 bit (0 or 1) may be associated with the data. Thus, in the present embodiment, the resistance level is set by the threshold voltage set in the ferroelectric FET 12, i.e., the state of the ferroelectric film. By using a ferroelectric film, it is possible to easily change the resistance level.

As will be described later, in the memory cell 10, it is also possible to provide the resistors 13 set to different resistance values for each of the partial cells 11. In this case, in the partial cell 11 including the ferroelectric FET 12 in which LVt is set, the resistance level becomes higher as the resistance value of the resistor 13 is higher. That is, the resistance level includes not only the level represented by the difference in the resistance value between the channel portion and the resistor 13, but also a level represented by the difference in the resistance value of the resistor 13. Such resistance levels may also be used to represent data.

The memory cell 10 stores data according to the resistance level set for each of the plurality of partial cells 11. In the memory cell 10, the resistor 13 connected to the ferroelectric FET 12 to which HVt is set (i.e., the ferroelectric FET 12 to be off-state) is selected. The selection combinations are one-to-one selection combinations of the N ferroelectric FETs 12 contained in the memory cell 10, and the number of selection combinations is 2^{N}. The memory cell 10 stores data represented by this combination, i.e., N-bit data. The data stored in the memory cell 10 may be read out by appropriately detecting the resistance value of the memory cell 10 as an electric signal (a current signal or a voltage signal). The ferroelectric FET 12 is a nonvolatile element that holds the polarization-state (threshold voltage Vt). Accordingly, the memory cell 10 operates as a nonvolatile memory cell.

### [Read Data]

In the present embodiment, data may be read from the memory cell 10 by using either the method of individually reading out the data stored in each of the partial cells 11 or collectively reading out the data stored in each of the partial cells 11. The following describes a method of reading data using individual readout and collective readout.

First, individual readout will be described. Individual readout is a method of accessing each partial cell 11 of the memory cell 10 and reading the data of the selected partial cell 11 from the memory cell 10. In the individual readout, the control voltage Vc is used. Here the control voltage Vc is, for example, a gate voltage set above HVt (Vr≥HVt). In the partial cell 11 where the control voltage Vc is applied, the ferroelectric FET 12 is turned on without approaching the set threshold voltage (HVt or LVt), and a low path of resistance is formed that does not pass through the resistor 13. Thus the control voltage Vc may be said to be a gate voltage for the channel portion to the conductive state (short) regardless of the high and low threshold voltages.

When performing individual readout, the partial cell 11 to be selected is applied a read voltage Vr, and the control voltage Vc is applied to the other partial cell 11. As a result, in the memory cell 10, a path is formed in which the channel portions of the unselected cells which have become conductive with respect to the selected partial cell 11 are connected in series. As a result, it is possible to refer to only the resistance level of the selected partial cell 11.

For example, when the partial cell 11b shown in FIG. 2 (ferroelectric FET 12b) is selected, the other ferroelectric FETs 12a and 12c are on-state regardless of the threshold-voltage value. At this time, when the ferroelectric FET 12b is set to HVt, the resistor 13b becomes the main conducting path. Further, when the ferroelectric FET 12b is set to LVt, the channel portion of the ferroelectric FET 12b becomes the main conducting path. The current or the like corresponding to the resistance value of the conducting path is detected as a data signal. As described above, in the individual readout, the resistance values of the partial cells 11 are individually read.

In the nonvolatile memory device 100, the resistance value of the resistor 13 may be set to the same value for each of the plurality of partial cells 11 included in the memory cell 10. As a result, the partial cells 11 may have the same configuration as each other. As a result, it is possible to align the level (level representing 0 or 1) of the data signal output from the memory cell 10, and it is possible to simplify the configuration and detection processing of the detection circuit or the like. The data signal may also be treated as a digital signal representing two levels. This may easily apply various processing circuits applicable to digital data processing.

FIG. 3 is a table showing an example of data stored in the memory cell 10. FIG. 3 shows an example of data stored in the memory cell 10 when the resistance values (Ra, Rb, Rc) of the resistors 13a to 13c are set equal to each other (Ra=Rb=Rc). As described with reference to FIG. 2, data corresponding to the threshold voltage set to each ferroelectric FETs 12a to 12c (FeFETs (a) to (c)) is set in the memory cell 10. In the table of FIG. 3, the ferroelectric FET 12 set to HVt is described as “H”, and the ferroelectric FET 12 set to LVt is described as “L”.

In FIG. 3, the data recorded by the ferroelectric FET 12 set to LVt and HVt are 0 and 1, respectively. For example, suppose that the ferroelectric FET 12a is set to HVt and the ferroelectric FETs 12b and 12c are set to LVt (second column of the table in FIG. 3). In this state, the data of (001) is recorded in the memory cell 10. Similarly, by setting the ferroelectric FETs 12a to 12c to H or L, the memory cell 10 may store data of 3 bits (2³=8 types) from (000) to (111). It is to be noted that these data may be individually read out for each partial cell 11 by the individual readout described above.

Next, the collective readout will be described. The collective readout is a method of reading the entire data recorded in the memory cell 10 at a time. In the collective readout, the entire data represented by the sum of the resistance levels of the partial cells 11 constituting the memory cell 10 is read. More specifically, the entire data is data represented by the overall resistance of the serial circuit (memory cell 10) of the partial cells 11 with the read voltage Vr applied to each partial cell 11. The entire data is typically multi-value data. Here, the multi-value data is data representing a value by three or more levels. The data representing the value of 0 or 1 is binary data.

When the collective readout is performed, for example, the read voltage Vr is applied to all the partial cells 11 included in the memory cell 10. Thus, each partial cell 11 has a state in which either the channel portion or the resistor 13 is selected as a path of the serial circuit. In this state, by referring to the entire resistance of the memory cell 10, the entire data, which is multi-value data, is read out.

In the nonvolatile memory device 100, the resistance value of the resistor 13 may be set to a different value for each of the plurality of partial cells 11 included in the memory cell 10. In this case, one memory cell 10 does not include the resistors 13 set to the same resistance value. As a result, the overall resistance of the memory cell 10 changes in accordance with the resistance value of the selected resistor 13. The amount of change is different for each selected resistor 13, i.e., partial cell 11. Thus, in the memory cell 10 having an N-bit configuration, multi-value data representing data values at 2^{N} levels may be recorded.

Incidentally, if the resistance value of each resistor 13 is the same, from the value of the overall resistance, it is not known which resistor 13 is selected, and it is conceivable that the number of levels that may be represented by the multi-value data is reduced. Therefore, by making the resistance values of the resistors 13 different from each other, it is possible to maximize the amount of data that may be represented as multi-value data.

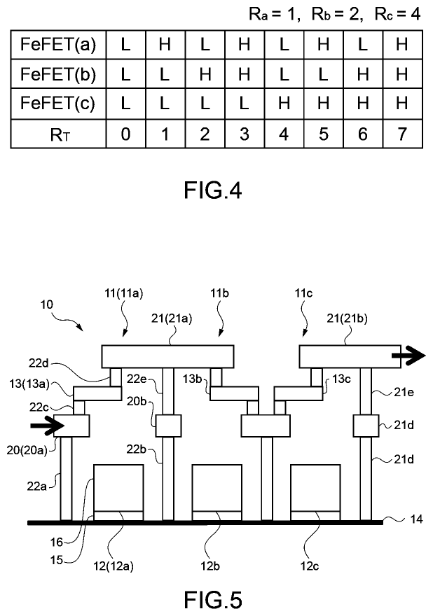

FIG. 4 is a table showing another example of data stored in the memory cell 10. FIG. 4 shows an example of data stored in the memory cell 10 when the resistance values Ra, Rb, and Rc of the resistors 13a to 13c are set to different values. When performing the collective readout, the ferroelectric FET 12 set to HVt is turned off, and the ferroelectric FET 12 set to LVt is turned on. Therefore, in the partial cell 11 of HVt, the resistance value is determined by the resistor 13, and in the partial cell 11 of LVt, the resistance value is determined by the channel portion. Here, the resistance value of the channel portion is 0. In this case, the total resistance R_{T} of the memory cell 10 is the sum of the resistance values of the resistors 13 of the partial cells 11 to which HVt is set.

In FIG. 4, the resistance value of the resistor 13a is set to Ra=1)(=1×2°, the resistance value of the resistor 13b is set to Rb=2 (=1×2¹), the resistance value of the resistor 13c is set to Rc=4 (=1×2²). In this manner, the resistance value of each resistor 13 is set to a value obtained by multiplying a predetermined value (1) by an integer power of 2. Thus, it is possible to set R_{T}, which increases or decreases by a predetermined value as steps.

For example, as shown in FIG. 4, if the ferroelectric FETs 12a to 12c are all LVts, then R_{T}=0. If only the ferroelectric FET 12a is HVt, then R_{T}=1. If only the ferroelectric FET 12b is HVt, then R_{T}=2. Thus, depending on the thresholds set for the respective ferroelectric FETs 12a to 12c, the total resistance R_{T} is a resistance of 0, 1, . . . , 7. Thus, it is possible to read the data signal that changes at the level of 3 bits (2³=8 types) as multi-value data.

By setting the resistance value of the resistor 13 so as to be proportional to the integer power of 2, it is possible to represent the value at equally spaced levels. Thus, it is possible to improve the detection accuracy of the level of the data signal (level of the multi-value data). It is also possible to simplify the configuration of the determination circuit or the like for determining the level. The method of setting the resistance value of each resistor 13 is not limited, and the resistance value may be set to an arbitrary value.

Thus, the memory cell 10 illustrated in FIG. 2 functions as a multi-value memory and may include a nonvolatile memory device 100 including a multi-value memory array. In this method, instead of storing a plurality of states in the ferroelectric film of the ferroelectric FET 12, multi-value data is stored as the resistance levels of the partial cells 11, and multi-value data is read out using the entire resistance R_{T} of the memory cell 10. In this manner, by combining the resistors and the memory function of the ferroelectric FET 12, data may be stably stored.

FIG. 5 is a schematic cross-sectional view showing a configuration example of the memory cell 10. In the present embodiment, the memory cell 10 is composed of the plurality of partial cells 11 formed on the same surface. Specifically, the partial cells 11 constituting the memory cell 10 are arranged in a planar shape along the surface of a predetermined semiconductor board 14 (typically Si board). In FIG. 5, a cross-sectional view of a memory cell 10 including three partial cells 11 arranged in a plane on a semiconductor board 14, cut along the thickness direction, is schematically illustrated.

The partial cell 11 includes the ferroelectric FET 12, the resistor 13, the first and second lower layer wirings 20a and 20b, the upper layer wiring 21, and the first to fifth contacts 22a to 22e. The ferroelectric FET 12 includes a ferroelectric film 15 stacked on a silicon board and a gate electrode 16 stacked on the ferroelectric film 15. On the upper layer of the ferroelectric FET 12, the lower layer wirings 20a and 20b, the resistor 13, and the upper layer wiring 21 are formed in this order.

In the partial cell 11, between the ferroelectric FET 12 (channel portion) and the upper layer wiring 21, a first path including the resistor 13 and a second path that does not include the resistor 13 are formed. The first path is a path that passes through the first contact 22a, the first lower layer wiring 20a, the third contact 22c, the resistor 13, and the fourth contact 22d in this order to connect them to the upper layer wiring 21. The second path is a path that passes through the second contact 22b, the second lower layer wiring 20b, and the fifth contact 22e in this order to connect them to the upper layer wiring 21. The first path (first contact 22a) is connected to one of the sources and drains of the ferroelectric FET 12, and the second path (second contact 22b) is connected to the other. Thus, a partial cell 11 in which the channel portion and the resistor 13 are connected in parallel is formed.

As shown in FIG. 5, in the ferroelectric FETs 12 adjacent to each other, the source of one ferroelectric FET 12 and the drain of the other ferroelectric FET 12 are connected to a common contact (first contact 22a or second contact 22b). Thus, in a chain cell structure in which the partial cells 11 are connected in series, the contact that connects to the source or drain of neighboring ferroelectric FETs 12 is common, and the element size may be reduced.

In the example shown in FIG. 5, the partial cells 11a to 11c are arranged in order from the left. The partial cell 11a has the ferroelectric FET 12a and the resistor 13a, the partial cell 11b has the ferroelectric FET 12b and the resistor 13b, and the partial cell 11c has the ferroelectric FET 12c and the resistor 13c. Of these, the drain of the ferroelectric FET 12a and the source of the ferroelectric FET 12b are connected to a common contact, and the drain of the ferroelectric FET 12b and the source of the ferroelectric FET 12c are connected to a common contact.

In the partial cell 11a, the first path connected to the upper layer wiring 21a via the resistor 13a is connected to the source of the ferroelectric FET 12a, and the second path connected to the upper layer wiring 21a is connected to the drain of the ferroelectric FET 12a. In the partial cell 11b, the second path common to the partial cell 11a is connected to the source of the ferroelectric FET 12b, and the first path connected to the upper layer wiring 21a via the resistor 13b is connected to the drain of the ferroelectric FET 12b. Therefore, the partial cells 11a and 11b are connected in series via a common upper layer wiring 21a.

In the partial cell 11c, the first path connected to the upper layer wiring 21b via the resistor 13c is connected to the source of the ferroelectric FET 12c. The first path through the resistor 13c is a path that passes through the path partially common to the first path, which passes through the resistor 13b of the partial cell 11b (the first contact 22a and the first lower layer wiring 20a), and connects to upper layer wiring 21b different from the upper layer wiring “a”. Also in the partial cell 11c, a second path connected to the upper layer wiring 21b is connected to the drain of the ferroelectric FET 12c. Therefore, the partial cell 11b and the partial cell 11c are connected in series via the common first lower layer wiring 20a.

For example, the first lower layer wiring 20a connected to the source of the first partial cell 11a is the source line 4, and the upper layer wiring 21b connected to the drain of the third partial cell 11c is the bit line 5. Here, it is assumed that a predetermined voltage is applied between the source line 4 and the bit line 5. In this case, the ferroelectric FET 12 in which HVt is set in the memory cell 10 is in an off-state even if the read voltage Vr is applied. Without passing through such an off-state ferroelectric FET 12, a current flows between the source line 4 and the bit line 5. In FIG. 5, the current flowing through the memory cell 10 is schematically illustrated using arrows.

At this time, the resistance value of the memory cell 10 (the resistance value between the first lower layer wiring 20a and the upper layer wiring 21b) is determined by the selection combinations of the three ferroelectric FETs 12 (2³=8). In the memory cell 10, a current corresponding to the resistance value of the memory cell 10 (eight resistance values) flows. This current is detected by a sense amplifier (not shown) or the like, and thereby data of three bits stored in the memory cell 10 may be read out.

Hereinafter, a specific element structure of the ferroelectric FET 12 and the resistor 13 will be described.

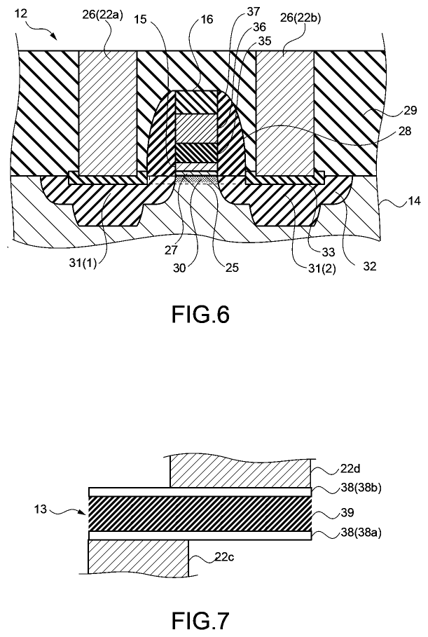

FIG. 6 is a schematic cross-sectional view illustrating an exemplary configuration of the ferroelectric FET 12. In FIG. 6, a cross-sectional view showing an element structure of one ferroelectric FET 12 is schematically illustrated. In FIG. 6, the illustration of the neighboring ferroelectric FET 12 is omitted. As described above, the ferroelectric FET 12 includes the ferroelectric film 15 and the gate electrode 16 stacked on the semiconductor board 14, and the ferroelectric FET 12 includes the active layer 25, the contact electrode 26, the interfacial layer 27, and the side walls 28. Further, on the semiconductor board 14, so as to fill the periphery of the ferroelectric FET 12, the interlayer film 29 is formed.

The semiconductor board 14 is made of a semiconductor material, on which the ferroelectric FET 12 (memory cell 10) is formed. The semiconductor board 14 is typically a Si board. In addition, the specific configuration of the semiconductor board 14 is not limited. For example, an SOI (Silicon on Insulator) board or the like sandwiching an insulating film such as SiO₂ to the Si board may be used. Also a board formed of other single element semiconductors such as germanium may be used, or a board formed of a compound semiconductor such as gallium arsenide (GaAs), gallium nitride (GaN), silicon carbide (SiC), or the like may be used.

In the present embodiment, the nMOSFET type element is formed as the ferroelectric FET 12. Therefore, the element region (a region separated by the element isolation layer 40 to be described later) is doped with a p-type impurity (for example, boron (B) or aluminum (Al)) as the first conductivity type impurity. Therefore, the element region is a P-well region in which a P-type well is formed. Incidentally, as the ferroelectric FET 12, even when the pMOSFET type element is used, the present technique is applicable.

The active layers 25 are regions that contribute to conductivity in the ferroelectric FET 12. The active layer 25 has a channel portion 30 in which a conducting path (channel) is formed, and contact portions 31 (source 1 or drain 2) provided at both ends of the channel portion 30. The channel portion 30 is formed in the element region where the p-type impurity of the semiconductor board 14 is doped. In FIG. 6, the channel portion 30 formed on the semiconductor board 14 is schematically illustrated as a shaded region. Incidentally, the contact portion 31, depending on the voltage or the like of the source line 4 and the bit line 5, functions as one of the source 1 or the drain 2.

The contact portion 31 is a region of the second conductivity type formed on the semiconductor board 14. The contact portion 31 is doped with an n-type impurity (for example, phosphorus (P), arsenic (As), or the like) as the second conductivity type impurity. In the example shown in FIG. 6, the NLDD portion 32 is formed in a deep area of the semiconductor board 14, and the n-type contact portion 31 is formed on its upper layer. The NLDD portion 32 is a light doped region (region in which impurity implantation is to be performed) having a lower concentration of impurities than the contact portion 31. The NLDD portion 32 is formed by doping the same n-type impurity as the contact portion 31. The contact portion 31 is formed by further doping an n-type impurity in the region where the NLDD portion 32 is formed.

Further, on the surface of the contact portion 31, refractory metal such as Ni is laminated and the silicide layer 33 (NiSi or the like) is thus formed. The silicidation process is performed in accordance with a step of generating a gate electrode, which will be described later. By providing the silicide layer, contact resistance with the contact electrode 26, which will be described later, may be reduced.

The interfacial layer 27 is provided on the surface of the semiconductor board 14 in which the channel portion 30 is formed. The interfacial layer 27 is a layer formed at the boundary between the ferroelectric film 15 and the semiconductor board 14. The interfacial layer 27 is formed of an insulating material. For example, the oxide film formed by oxidizing the surface of the semiconductor board 14 serving as the channel portion 30 (silicon oxide film or the like) becomes the interfacial layer 27.

The ferroelectric film 15 is a gate dielectric film formed by stacking ferroelectric materials. As shown in FIG. 6, the ferroelectric film 15 is formed on an upper layer of the interfacial layer 27. A gate electrode 16, which will be described later, is formed on the ferroelectric film 15. For example, the electric field acting on the channel portion 30 of the active layer 25 via the gate electrode 16 changes in accordance with the spontaneous polarization of the ferroelectric film 15 which is the gate dielectric film. Thus, it is possible to set the threshold voltage for controlling the conduction of the channel portion 30 to a high value (HVt) or a low value (LVt).

As the ferroelectric film 15, a ferroelectric material which causes spontaneous polarization and whose direction of spontaneous polarization may be controlled using an external electric field is used. As such a material, for example, a ferroelectric material such as hafnium (HfOₓ), zirconium (ZrOₓ), or an HfZrOₓ is used. Alternatively, the ferroelectric film 15 may be formed by doping atoms such as lanthanum (La), silicon (Si), or gadolinium (Gd) into a film formed of the above-described oxide-based ferroelectric material. Alternatively, perebskite-based ferroelectric materials such as lead zirconate titanate (Pb(Zr,Ti)O₃: ZT) and strontium bismuth tantalate (SrBi₂Ta₂O: BT) may be used. Further, the ferroelectric film 15 may be a single layer or a plurality of layers.

The gate electrode 16 is formed on the ferroelectric film 15 and functions as the word line 6 described with reference to FIGS. 1 and 2. As shown in FIG. 6, the gate electrode 16 has a metal electrode layer 35, a polysilicon layer 36, and a silicide layer 37. Thus, the gate electrode 16 is the wiring of the laminated structure in which these layers are stacked.

The metal electrode layer 35 is formed on the ferroelectric film 15, and is an electrode made of metal or an alloy. The metal electrode layer 35, for example, titanium nitride (TiN) or tantalum nitride (TaN) or the like is used. The polysilicon layer 36 is formed on the metal electrode layer 35. The silicide layer 37 is formed as an upper layer of the polysilicon layer 36, and is a layer in which a refractory metal is laminated on the polysilicon layer 36 to be silicided. Nickel (Ni), for example, is used as the refractory metal, and the silicide layer 37 is made of nickel silicide (NiSi), for example. In this manner, by forming the gate electrode 16 with a stacked layer structure, the wiring resistance may be sufficiently lowered as compared with an electrode formed of, for example, a polysilicon single layer.

The side wall 28 is made of an insulating material, and is a side wall provided on the side surface of the gate electrode 16. The side wall 28, for example, is formed by uniformly forming an insulation film in a region including the gate electrode 16, and performing a perpendicular anisotropic etching with respect to the formed insulating film. As the side wall 28, for example, silicon oxide (SiOₓ), silicon nitride (SiNₓ), silicon oxidride (SiON), or the like is used.

The side wall 28 shields the second conductivity type impurity doped in the contact portion 31 of the semiconductor board 14 to protect the channel portion 30. The channel portion 30 is formed directly below the gate electrode 16, and each contact portion 31 (source 1 or drain 2) is electrically connected via the channel portion 30. Thus the side wall 28 defines the positional relationship between each contact portion 31 and the channel portion 30 and the gate electrode 16.

The contact electrode 26 is an electrode formed by filling a through hole (contact hole) formed through the interlayer film 29. The contact electrodes 26 are connected to the contact portions 31 formed on both sides of the channel portion 30 (source 1 or drain 2). The contact electrodes 26 serve as the first contact 22a and the second contact 22b described with reference to FIG. 5. Hereinafter, the contact electrodes 26 formed on the left side and the right side in the drawing may be described as first and second contacts 22a and 22b.

As the contact electrode 26 (first and second contacts 22a and 22b), for example, a low resistance metal such as titanium (Ti) or tungsten (W), or a metal compound such as titanium nitride (TiN) or tantalum nitride (TaN) is used. For example, these electrode materials are filled in the contact holes to form the contact electrodes 26. The contact electrode 26 may be formed as a single layer or a stacked body.

On the semiconductor board 14, so as to fill the periphery of the ferroelectric FET 12, the interlayer film 29 is formed. The interlayer film 29 is made of an insulating material and is formed over the entire surface of the semiconductor board 14 so as to cover each memory cell 10 formed on the semiconductor board 14. A planarization process is performed on the upper layer of the interlayer film 29 to form the resistor 13 and the like, which will be described later. A contact hole for forming the contact electrode 26 is formed in the interlayer film 29. An SiO2 film is typically used as the interlayer film 29. Alternatively, insulating materials such as silicon oxide (SiOₓ), silicon nitride (SiNₓ), or silicon oxynitride (SiON) may be used as the interlayer film 29.

FIG. 7 is a schematic sectional view showing a configuration example of the resistor 13. In FIG. 7, a cross-sectional view showing the element structure of the resistor 13 connected to the third contact 22c and the fourth contact 22d is schematically illustrated. The resistor 13 includes a pair of electrode films 38 and a resistor film 39 sandwiched between the pair of electrode films 38. The resistance value of the resistor film 39 connected via these electrode films 38 becomes the resistance value of the resistor 13.

The electrode film 38 includes a lower electrode film 38a and an upper electrode film 38b. The lower electrode film 38a is an electrode connected to the third contact 22c formed on the lower layer side of the resistor 13. The upper electrode film 38b is an electrode connected to the fourth contact 22d formed on the upper layer side of the resistor 13. Each electrode film 38 is typically formed using the same electrode material, but may be formed using different electrode materials. As the electrode material of the electrode film 38, for example, a metal compound such as titanium nitride (TiN) or tantalum nitride (TaN), or a low resistance metal such as titanium (Ti) or tungsten (W) is used.

The resistor film 39 is formed on the lower electrode film 38a. An upper electrode film 38b is formed on the resistor film 39. The material of the resistor film 39 may be appropriately selected so that, for example, the resistor 13 has a desired resistance value. For example, a metal compound, a semiconductor film, a metal oxide film, an insulating film, or the like may be used as the resistor film 39. Alternatively, a combination of these materials may form the resistor film 39. The type and the like of the material of the resistor film 39 are not limited.

In the resistor 13, for example, the shapes of the electrode films 38 and the resistor films 39 are set to be the same shapes as each other. In this case, the upper layer side and the lower layer side of the resistor film 39 are both covered with electrodes. Thus, it is possible to easily control the resistance value of the resistor 13 by changing the area of the resistor film 39 (area of the pattern). In addition, since the films have the same shape, it is possible to pattern the resistor 13 in one lithography process. In addition, the specific configuration of the resistor 13 is not limited, and the present technique may be applied to, for example, a case where the resistor 13 having different shapes and areas from those of the electrode film 38 and the resistor film 39 is used.

### [Method for Manufacturing Nonvolatile Memory Device]

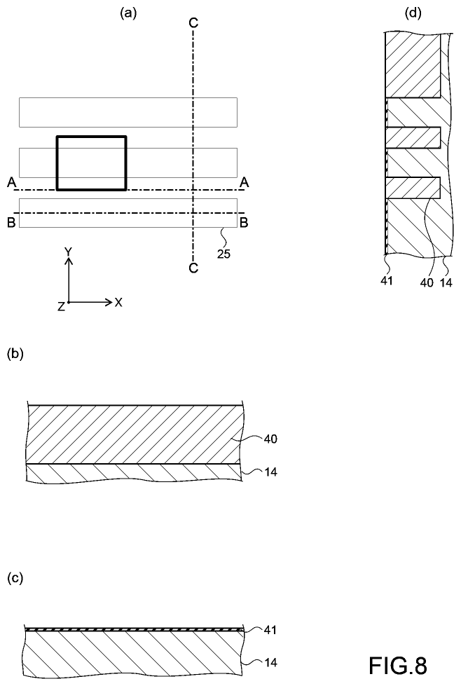

FIGS. 8 to 15 are plan views and cross-sectional views showing each step of the manufacturing method of the nonvolatile memory device 100. In each of FIGS. 8 to 15, a plan perspective view of the semiconductor board 14 (nonvolatile memory device 100) seen from the thickness direction (a), a cross-sectional view at AA line (b), a cross-sectional view at BB line (c), and a cross-sectional view at CC line (d), the lines being shown in the plan perspective view (a), are schematically illustrated. In the figures shown in FIGS. 8 to 15, the steps of forming two ferroelectric FETs 12a and 12b adjacent to each other in the memory cell 10 are shown, and illustrations of other ferroelectric FETs 12 or the like are omitted.

Hereinafter, a method of manufacturing the nonvolatile memory device 100 will be described with reference to FIGS. 8 to 15. The lateral and vertical directions in the plan perspective view (a) are described as the X and Y directions, respectively, and the thickness direction perpendicular to the X and Y directions is described as the Z direction. The above-mentioned AA line is a line for cutting the element isolation layer 40 along the X direction, and the BB line is a line for cutting the element region along the X direction. The CC-line is a line for cutting between neighboring ferroelectric FETs 12 along the Y-direction.

FIG. 8 shows a step of forming isolation elements for isolating the ferroelectric FET 12. Specifically, by forming the element isolation layer 40 on the semiconductor board 14, the element region of the ferroelectric FET 12 is formed. Here, the element isolation layer 40 is formed by the STI method. The Si board is used as the semiconductor board 14.

First, an SiO₂ film and a Si₃N₄ film is accumulated on the semiconductor board 14 in this order. The SiO₂ film is formed, for example, by dry-oxidizing an Si-board. Further, the Si₃N₄ film is formed by decompression CVD (Chemical Vapor Deposition). Subsequently, resist patterning is performed on a portion where the active layer 25 is to be formed. Using this pattern as a mask, the Si₃N₄ film/SiO₂ film/Si board are sequentially etched to form a groove-like trench region. At this time, the semiconductor board 14 performs etching at a depth of, for example, 350 to 400 nm.

In FIG. 8 (a), a rectangular pattern formed along the X direction is a region (resist pattern) where the active layer 25 is formed. Therefore, the region outside the resist pattern becomes the trench area. The trench region is provided with a field oxide film which is an element isolation layer 40. The pattern area where the Si₃N₄ film is left becomes the active layer 25.

After forming the trench region, the trench region is embedded with the SiO₂ film to form an element isolation layer 40. For example, by performing filling by high-density plasma CVD, it is possible to form a dense film with good step coverage. At this time, the stacked film thickness of the SiO₂ film is, for example, 650 to 700 nm. Subsequently, polishing is performed using a Chemical Mechanical Polish (CMP) method to planarize the deposited the SiO₂ film. At this time, the pattern area where the Si₃N₄ film is left is polished to the extent that the SiO₂ film on the Si₃N₄ film may be removed.

Subsequently, the Si₃N₄ film is removed by using thermal phosphoric acid to form the active layer 25 (active region). It should be noted that prior to process with thermal phosphoric acid, the board 14 may be annealed in a N₂, O₂ or H₂/O₂ environment. By the annealing process, the SiO₂ film of the element isolation layer 40 may be made a denser film, rounding may be performed to round the corners of the active layer 25, and the like.

Subsequently, the surface of the active layer 25 is oxidized to form a sacrificial oxide film 41. The thickness of the sacrificial oxide film 41 is, for example, about 10 nm. After the sacrificial oxide film 41 is formed, ions of an impurity of the first conductivity type (e.g., boron (B)) are implanted into a region where an MOSFET (ferroelectric FET 12) is to be formed. As a result, the active layer 25 on the semiconductor board 14 (Si board) is converted into a well region (P-well region) of the first conductivity type.

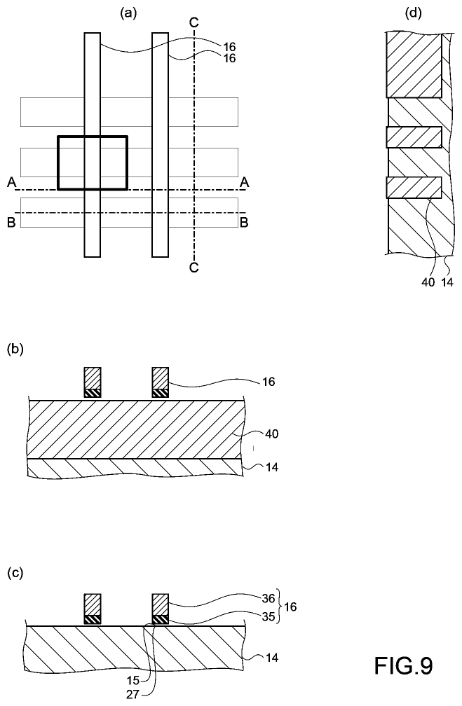

FIG. 9 shows a step of forming the ferroelectric film 15 and the gate electrode 16. Specifically, the film serving as the ferroelectric film 15 and the gate electrode 16 is laminated over the entire surface of the semiconductor board 14, and the laminated film is shaped in accordance with the pattern of the gate electrode 16.

First, the sacrificial oxide film 41 formed in FIG. 8 is peeled off using a hydrogen fluoride (HF) solution. Thereafter, the interfacial layer 27 is formed on the exposed Si board surface. The thickness of the interfacial layer 27 is set to approximately 0.5 to 1.5 nm. For forming the interfacial layer 27, an RTO (Rapid Thermal Oxidization) method, an oxygen-plasma treatment, or a chemical oxidation method (Chemical Oxide) using a peraqueous chemical treatment is used.

Subsequently, the ferroelectric film 15 is laminated. As the ferroelectric film 15, for example, a hafnium oxide (HfOₓ) film is used. The thickness of HfOₓ film is set to, for example, about 3 to 10 nm. The HfOₓ film is formed by, for example, the CVD method, an ALD (Atomic Layer Deposition) method, or the like. In addition, a ferroelectric film 15 may be formed using HfZrOₓ, PZT, SBT or the like. The ferroelectric film 15 may be doped with atomics such as La, Si, and Gd.

Subsequently, the gate electrode 16 is laminated. First, as the metal electrode layer 35, titanium nitride (TiN) or tantalum nitride (TaN) is deposited. The thickness of the metal electrode layer 35 is set to, for example, about 5 to 20 nm. As a method of depositing the metal electrode layer 35, the sputtering method, the CVD method, the ALD method, or the like may be used.

Subsequently, a polysilicon layer 36 is stacked on the metal electrode layer 35. The thickness of the polysilicon layer 36 is set to, for example, about 50 to 150 nm. The polysilicon layer 36 is formed by, for example, a low-pressure CVD method using SiH₄ as a material gas. The deposition temperature at this time is set to, for example, about 580° C. to 620° C.

After the polysilicon layer 36 has been deposited, a resist pattern of the gate electrode 16 is lithographically formed on the polysilicon layer 36. Using this resist pattern as a mask, anisotropic etching using hydrogen bromide (HBr) or chlorine (Cl) based gas is performed, and the polysilicon layer 36, the metal electrode layer 35, the ferroelectric film 15, and the interfacial layer 27 are etched in this order. Thus, a wiring pattern of the gate electrode 16 including the ferroelectric film 15 is formed. As shown in FIG. 9 (a), in the present embodiment, a wiring pattern extending along the Y direction is formed.

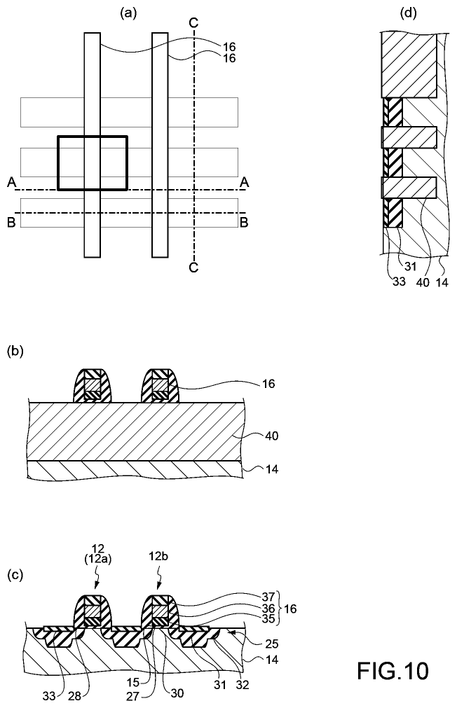

FIG. 10 shows a step of forming a ferroelectric FET (FeFET) including a ferroelectric film 15 as a gate dielectric film. Specifically, the side wall 28 is formed on the side surface of the gate electrode 16, and the second conductivity type impurity (n-type impurity) is doped in the contact region.

First, arsenic ions (As+) as second conductivity type impurities are implanted into both sides of the gate electrode 16 to form the NLDD portion 32. At this time, the acceleration voltage is set to, for example, about 5 keV to 20 keV, and the concentration of ion injection is set to, for example, about 5 to 20×10¹³/cm². By forming the NLDD portion 32, the short-channel effect is suppressed, and it is possible to reduce the variation of the FET characteristics of the ferroelectric FET 12. As the second conductivity type impurity, phosphorus (P) may be used.

Subsequently, the side walls 28 are formed. First, an SiO₂ film is accumulated with a film thickness of 10 to 30 nm by the plasma CVD method, and then a Si₃N₄ film is accumulated with a film thickness of 30 to 50 nm by the plasma CVD method to form an isolated film for the side wall 28. Next, the deposited insulating film (Si₃N₄ film/SiO₂ film) is etched by anisotropic etching to form the side walls 28 on the side surfaces of the gate electrodes 16.

After forming the side walls 28, arsenic ions (As+) as second conductivity type impurities are implanted to form n-type contact portions 31 (source/drain regions) on both sides of the gate electrode 16. At this time, the acceleration voltage is set to, for example, about 20 keV to 50 keV, and the concentration of ion injection is set to, for example, about 1 to 5×10¹⁵/cm². In addition, the ion-implanted impurities (dopants) are activated by RTA (Rapid Thermal Annealing) at an annealing temperature of 1000° C. for 5 seconds. Thus, a MOSFET is formed. In addition, in order to promote activation of impurities and to suppress diffusion of impurities, an annealing process may be performed using a spiked RTA or the like. Thus, in the manufacturing process of the plurality of partial cells 11 (memory cells 10), a MOSFET for controlling the conduction of the channel portion 30 is formed.

In FIG. 10 (c), the cross-section of the ferroelectric FET 12a adjacent to each other (left side) and the ferroelectric FET 12b (right side) is shown. Between the ferroelectric FETs 12a and 12b, a common contact portion 31 is provided. The contact portion 31, for example, functions as the drain 2 of the ferroelectric FET 12a, and also functions as the source 1 of the ferroelectric FET 12b. Thus, the chain cell type memory cell 10 does not need to provide two contact portions 31 individually (source contact and drain contact) for each element. Thus, the element area of the memory cell 10 is greatly reduced, making it possible to achieve high integration.

Subsequently, a nickel (Ni) film is deposited over the entire surface of the semiconductor board 14 using the sputtering method or the like. The thickness of the nickel film is set to, for example, about 6 to 8 nm. Ni deposited on Si is silicided by performing RTA for 10 to 60 seconds at an annealing temperature of 300 to 450° C. after deposition of the nickel film. The Ni deposited on SiO₂ of the field oxide layer 40 remains unreacted. For example, an H₂SO₄/H₂O₂ or the like is used to remove the unreacted Ni film. Consequently, on the contact portion 31 and the gate electrode 16, the silicide layers 33 and 37 made of low-resistance nickel silicide (NiSi) are formed. In addition, instead of the Ni film, a Co film, a NiPt film, or the like may be deposited to form a CoSi₂, a NiPtSi, or the like. For example, by setting the temperature and time of RTA as appropriate, these silicides may be formed.

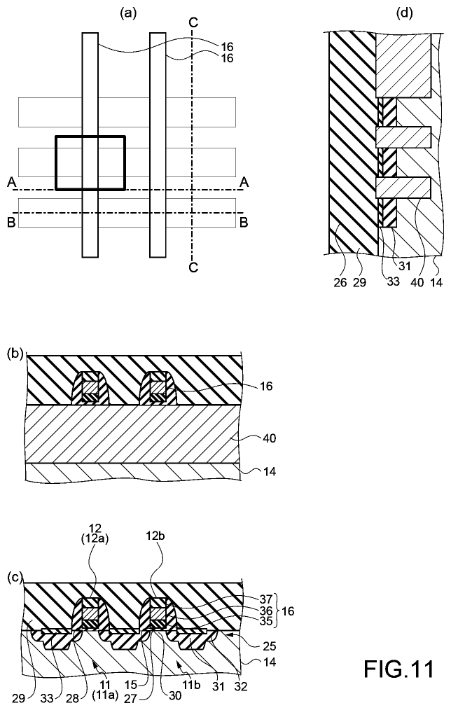

In FIG. 11, the step of forming the interlayer film 29 is shown. Specifically, a stopper liner film (not shown) and the interlayer film 29 are deposited in this order, and a planarization process is performed. The stopper liner film functions as a stopper for controlling etching when the contact hole 45 described later is formed.

First, a stopper liner film is deposited over the entire surface of the semiconductor board 14. As the stopper liner film, a silicon nitride (SiN) film is used, and the film thickness is set to about 10 to 50 nm. The stopper liner film is formed by a plasma CVD method, a low-pressure CVD method, the ALD method, or the like. The stopper liner film may also be formed as a layer for applying compressive stress or tensile stress.

Subsequently, by the CVD method, the interlayer film 29 is deposited over the entire surface of the semiconductor board 14. As the interlayer film 29, an SiO₂ film is used, and the film thickness thereof is set to, for example, about 100 nm to 500 nm. After the interlayer film 29 is formed, the upper layer of the interlayer film 29 is flattened by CMP.

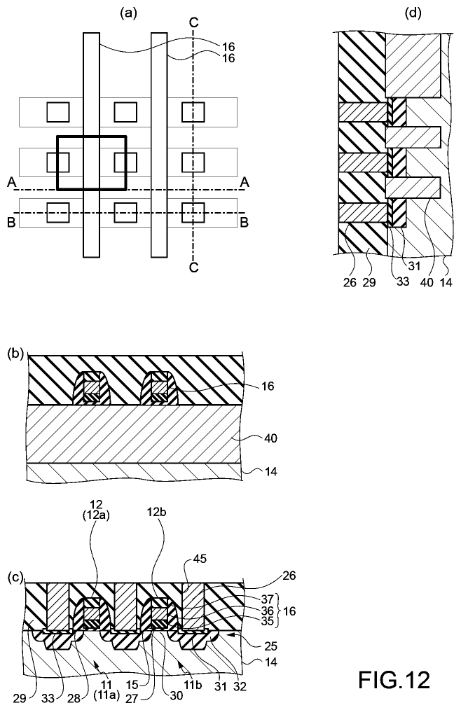

FIG. 12 shows a step of forming the contact electrode 26. Specifically, contact holes 45 are formed in the interlayer film 29, and the contact electrode 26 is formed so as to fill the contact holes 45.

First, a plurality of contact holes 45 penetrating the interlayer film 29 are formed. The contact hole 45 is formed so as to be connected to each contact portion 31 (silicide layer 33) of the active layer 25. The contact hole 45 connected to the gate electrode 16 (not shown) is formed. The contact hole 45 is formed by etching the interlayer film 29. At this time, the SiO₂ film is selectively etched under an etching condition in which the selection ratio of SiO₂/SiN (interlayer film 29/stopper liner film) is high. Thus, since the etching stops at the stopper liner film, it is possible to increase the controllability of the etching up to the silicided portions (contact portion 31 and the silicide layer 33).

After the contact hole 45 is formed, Ti and TiN are deposited by the CVD method or the like, and W is further deposited to fill the contact hole 45 with an electrode material. Thereafter, flattening is performed by the CMP method to remove the excess electrode material. As a result, the contact electrode 26 is formed. The contact electrode 26 is a W-PLUG in which the tungsten is exposed in the upper layer. Note that Ti and TiN may be formed by the sputtering method using Ion Metal Plasma (IMP) or the like instead of the CVD method. Alternatively to the CMP method, flattening may be performed using front etch-back.

These contact electrodes 26, in the ferroelectric FET 12, function as the first contact 22a and the second contact 22b. In the logic region, these contact electrodes 26 function as a contact for connecting the source electrode, the drain electrode, the gate electrode, and the respective wirings.

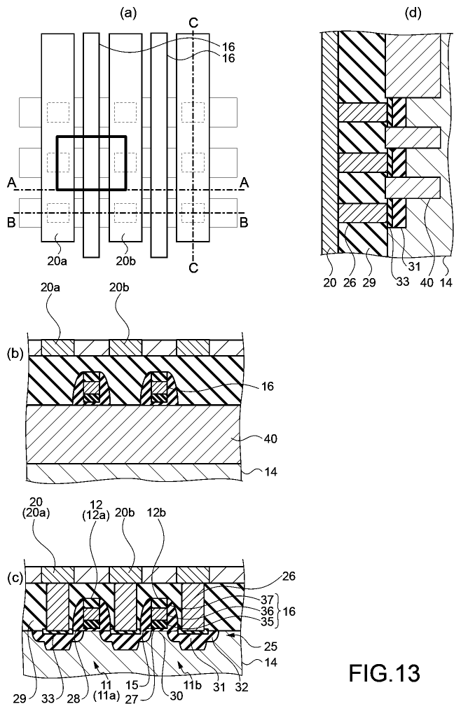

FIG. 13 shows a step of forming the lower layer wiring 20. Specifically, the first lower layer wiring 20a for connecting one contact portion 31 of the ferroelectric FET 12 to the resistor 13, and the second lower layer wiring 20b for connecting the other contact portion 31 to the upper layer wiring 21 are formed as the same wiring layer. The wiring layer is also used as a wiring constituting another peripheral circuit such as a CMOS circuit.

For example, wiring material such as Cu using the damascene structure is deposited, and the wiring pattern of the first and second lower layer wirings 20a and 20b is formed. The wiring pattern is a rectangular pattern extending along the Y direction so as to connect with each contact electrode 26 of the adjacent ferroelectric FET 12 through the element isolation layer 40. Thus, the first and second lower layer wirings 20a and 20b are wirings connected to the sources 1 and drains 2 of the ferroelectric FET 12. It is also possible to form a wiring such as Al in place of Cu.

In the memory cell 10, at least one of the lower layer wiring 20 (the first lower layer wiring 20a or the second lower layer wiring 20b) connected to both ends of the plurality of partial cells 11 (ferroelectric FET 12) connected in series may be used as the source line 4 or the bit line 5. For example, it is desirable to arrange the wiring serving as the source line 4 and the bit line 5 orthogonally to each other. Therefore, when the lower layer wiring 20 extending in the Y direction is the source line 4 (bit line 5), the bit line 5 (source line 4) extending in the X direction is configured by using other wiring (such as the upper layer wiring 21).

For example, in the three-bit memory cell 10 described with reference to FIG. 5, the first lower layer wiring 20a connected to the leftmost partial cell 11a is used as the source line 4. On the other hand, when the source line 4 is provided as another wiring, for example, in the three-bit memory cell 10 shown in FIG. 5, it is also possible to use the second lower layer wiring 20b connected to the right end partial cell 11c as the bit line 5. In any case, as in the circuit diagram described with reference to FIG. 2, the source line 4 and the bit line 5 may be appropriately set so that the partial cells 11 may be connected in series.

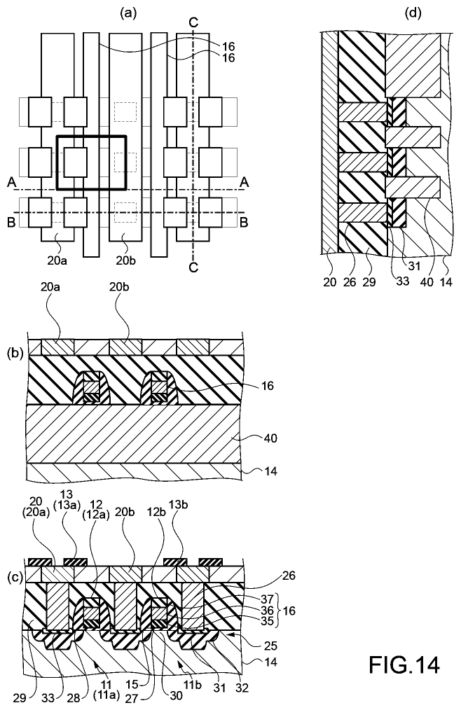

FIG. 14 shows a step of forming the resistor 13. Specifically, the resistor film 39 sandwiched between the electrode films 38 is formed in a predetermined pattern so as to be connected to the first lower layer wiring 20a. In FIG. 14, the electrode film 38 is not shown. Here, a step of not forming the third contact 22c described with reference to FIG. 5 will be described. Needless to say, a manufacturing process of connecting the resistor 13 and the first lower layer wiring 20a via the third contact 22c may be performed.

First, over the entire surface of the board on which the lower layer wiring 20 is formed, the lower electrode film 38a is deposited, and then the resistor film 39 is deposited, followed by depositing the upper electrode film 38b. As the lower electrode film 38a and the upper electrode film 38b, Ti, TiN, or the like is deposited by the CVD method or the like. As the resistor film 39, a resistive material (e.g., an insulating film, a metal compound, a semiconductor film, polysilicon, or the like) selected so as to obtain a desired resistance value is deposited by the CVD method, the sputtering method, or the like. For example, when an insulating film is used as a resistive material, the film thickness is set to about 1 to 3 nm.

Next, a resist pattern of the resistor 13 is formed on the upper electrode film 38b by lithography. Using this resist as a mask, the upper electrode film 38b, the resistor film 39, and the lower electrode film 38a are etched in this order. As a result, the plurality of resistors 13 may be patterned by one lithography process and one etching process. The pattern of the resistor 13 is appropriately formed so as to be connected to the corresponding first lower layer wiring 20a. Thus, in the manufacturing process of the plurality of partial cells 11 (memory cell 10), the resistors 13 connected in parallel to the channel portion 30 are formed.

For example, in FIG. 14 (c), on the first lower layer wiring 20a connected to the ferroelectric FET 12a, two resistors 13 connected to the left and right sides of the wiring are formed. Of these, the resistor 13 formed on the right side which is directly above the ferroelectric FET 12a becomes the resistor 13a which is connected in parallel with the ferroelectric FET 12a. Similarly on the first lower layer wiring 20a connected to the ferroelectric FET 12b, two resistors 13 connected to the left and right sides of the wiring are formed. Of these, the resistor 13 formed on the left side which is directly above the ferroelectric FET 12b is the resistor 13b which is connected in parallel with the ferroelectric FET 12b. In FIG. 14, illustration of the ferroelectric FETs 12 corresponding to the other resistors 13 other than the resistors 13a and 13b is omitted.

The resistance value of the resistor 13 is set, for example, in the range of 1 kΩ to 1 MΩ. By setting the resistance value in this range, the detection efficiency in the sense amplifier or the like for detecting the output (current or the like) of each memory cell 10 is improved, and it is possible to detect at high speed when detecting the data. As a resistance material for setting a desired resistance value in the range of 1 kΩ to 1 MΩ, any of a metal compound, a semiconductor film, an insulating film, and the like may be used. For example, a desired resistance value may be easily set by appropriately controlling the film thickness in addition to the selection of each resistance material. Alternatively, the resistor 13 may be formed by sandwiching polysilicon or the like with electrode films. In this case, for example, by appropriately setting the ion injection density of about 1×10¹³/cm² to 1×10¹⁶/cm² in ion injection such as arsene (As) or phosphorus (P) to polysilicon, it is possible to adjust the resistance value with high accuracy and easily.

The resistance value of the resistor 13 may be set, for example, in the range of 1 MΩ to 1 GΩ. By setting the resistance value in this range, it is possible to suppress the current and unnecessary leakage current or the like at the time of data detection. In addition, when the present invention is applied to a multiply-accumulate operation device or the like, which will be described later, it is possible to adjust the time constant of the output within an appropriate range. As a resistance material for setting a desired resistance value in the range of 1 MΩ to 1 GΩ, any of a metal compound, a semiconductor film, an insulating film, and the like may be used. For example, the resistor 13 having a relatively high resistance value may be formed by a structure in which an isolated film such as SiOₓ, AlOₓ, HfOₓ, ZrOₓ, and MgOₓ is sandwiched by electrode films. Of course, it is also possible to use another material.

In addition, the size and shape of the resistor 13 may be arbitrarily set regardless of which resistive material is used. For example, as described with reference to FIG. 7, the resistance value of the resistor 13 is adjustable by the area of the resistor film 39. By adjusting the resistance value using the area, without changing the order of the resistance value, it is possible to perform fine adjustment of the resistance value.

The area of the resistor film 39 is set to the same value for each of the plurality of partial cells 11 included in the memory cell 10. Thus, the resistance value of each resistor 13 is equal to each other. In this manner, by equalizing the resistance value of the resistor 13 for each partial cell 11, for example, the level of the data signal, such as the current value output from the memory cell 10, may be made uniform. As a result, it is possible to unify the configuration of the sense amplifier or the like for detecting the data signal, and to simplify the readout process. Such a configuration is implemented in a nonvolatile memory device 100 for performing the individual readout described with reference to FIG. 3 and the like.

The area of the resistor film 39 may be set to a different value for each of the plurality of partial cells 11 included in the memory cell 10. In this case, the resistance value of each resistor 13 is a different value from each other. Thus, by varying the resistance value of the resistor 13 for each partial cell 11, it is possible to represent the data value by the magnitude of the data signal. As a result, the memory cell 10 may store multi-value data and output a data signal representing the multi-value data. In this case, the data signal may be treated as an analog signal representing multi-value data.

For example, the area of the resistor film 39 is set to 1 times, 2 times, 4 times, 8 times, or the like of the reference area. Assuming that the resistance value of the resistor film 39 of the reference area is R, the resistance values of the resistor films of 2 times, 4 times, and 8 times the reference area are R/2, R/4, and R/8, respectively. Thus, in the present embodiment, by appropriately setting the area of the resistor film 39 (resistor 13), it is possible to easily form the resistor 13 having different resistance values from each other without changing or increasing the process step. Such a configuration is implemented in a nonvolatile memory device 100 for performing the collective readout described with reference to FIG. 4 and the like.

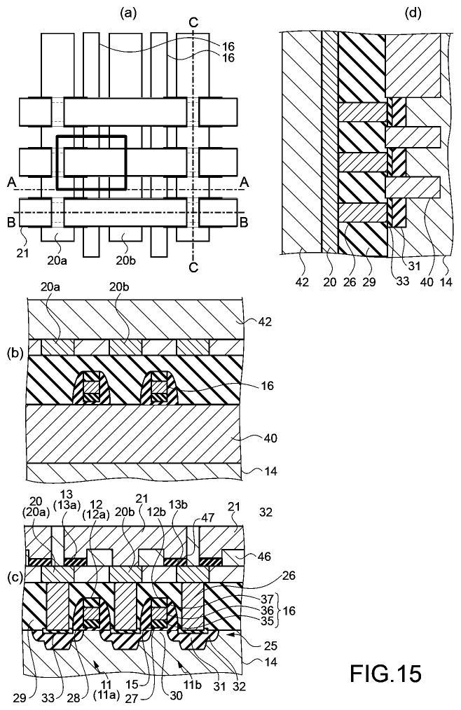

FIG. 15 shows a step of forming the upper layer wiring 21. Specifically, the upper layer wiring 21 connecting the ferroelectric FETs 12 adjacent to each other in series, and the upper layer wiring 21 serving as the source line 4 or times bit line 5 (not shown) are formed as the same wiring layer. The wiring layer is also used as a wiring constituting another peripheral circuit such as a CMOS circuit.

First, an interlayer film 46 is formed on the resistor 13. As the interlayer film 46, an SiO₂ film or the like deposited by the CVD method is used, and the film thickness thereof is set to, for example, about 100 nm to 500 nm. After the interlayer film 46 is formed, the upper layer of the interlayer film 46 is planarized by CMP. Subsequently, a plurality of contact holes 47 penetrating the interlayer film 46 are formed. The contact holes 47 are formed by etching the interlayer film 46 so as to connect to the upper layer electrode film 38b and the second lower layer wiring 20b of each resistor 13. Before forming the interlayer film 46, a stopper liner film or the like may be formed to enhance the controllability of etching.

After the formation of the contact hole 47, a wiring material such as Cu using a dual damascene structure is deposited, and the pattern of the upper layer wiring 21 is formed. At this time, the contact hole 47 is filled with the wiring material of the upper layer wiring 21, and the upper layer contacts 22d and 22e are formed. Incidentally, as the upper layer wiring 21, it is also possible to form a wiring such as Al.

As shown in FIG. 15 (a) and (c), the upper layer wiring 21 is a wiring connected to the resistor 13a corresponding to the ferroelectric FET 12a, the resistor 13b corresponding to the ferroelectric FET 12b, and the contact portion 31 common to the ferroelectric FETs 12a and 12b. Thus, a partial cell 11a in which the ferroelectric FET 12a and the resistor 13a are connected in parallel, and a partial cell 11b in which the ferroelectric FET 12b and the resistor 13b are connected in parallel are formed. At the same time, the partial cells 11a and 11b are connected in series. By repeatedly providing such a structure, an N-bit memory cell 10 may be formed.

According to the above steps, the nonvolatile memory device 100 according to the present embodiment may be formed. Note that the above-mentioned materials, numerical values, and the like are examples, and may be appropriately changed in accordance with the configuration of the apparatus and the like.

As described above, in the nonvolatile memory device 100 according to the present embodiment, the resistors 13 are connected in parallel to the channel portions 30 of the ferroelectric FETs 12 to form the partial cells 11, and the plurality of partial cells 11 are connected in series to form the memory cell 10. Data is stored in the memory cell 10 according to the resistance level of each partial cell 11. This may realize an element having a nonvolatile memory function capable of stably storing data and achieving high integration.

In recent years, various circuits using elements having a nonvolatile memory function have been developed. For example, there is known a CMOS circuit in which nMOSFETs and pMOSFETs are configured on the same board. CMOS circuits are widely used as many LSI configuration devices because of their low power dissipation, easy miniaturization, easy high integration, and high-speed operation. Especially, LSIs equipped with multifunctions on a single chip together with analog circuits and memories are commercialized as a so-called system-on-chip (SoC). A SRAM (Static Random Access Memory) has been used as a memory for these products, but in recent studies, various types of memories are incorporated in order to reduce costs and consume less power.

For example, instead of an SRAM, there is a method of additionally using a DRAM (Dynamic Random Access Memory), but the application of SRAM or DRAM may be limited because it is a volatile memory in which the data is lost when the power is turned off. On the other hand, nonvolatile memories for holding data even when power is turned off, such as a ferroelectric memory (FeRAM) using a ferroelectric material, have been developed. These memories may be used not only as SoCs but also as memory chips alone. In addition, in a memory element, by storing a plurality of bits in one memory cell, cost reduction and low power consumption due to reduction in element area are expected.

For example, it is possible to configure a nonvolatile multi-value memory for storing multi-value data by changing the polarization amount of a ferroelectric formed as a gate dielectric film. In this case, different states of the threshold voltage Vt is stored by changing the amount of polarization. However, when writing or erasing is performed by changing the amount of polarization at a constant voltage, there is a possibility that Vt varies greatly due to variations in the domain state of the ferroelectric. In order to avoid such variations in Vt, it is necessary to perform verification processing for checking Vt for each bit and rewriting of Vt, which may decrease the writing speed. Peripheral circuits may also increase and power consumption may increase.

For example, as shown in Japanese Patent Application Laid-Open No. 2005-277170, it is possible to configure a memory cell having a chain cell structure (a multi-bit cell structure) by using a ferroelectric capacitor. By using the chain cell structure, the cell area may be reduced. In addition, by reducing the connection of the bit lines, parasitic capacitance and the like may be reduced, and, for example, power consumption at the time of writing may be reduced. However, in such a configuration, a MOSFET for accessing needs to be provided for each of a plurality of bit cells, and the entire area may be increased. When data is read from a ferroelectric capacitor, destructive reading is generally performed. For example, at the time of reading, since the data held by the ferroelectric substance is rewritten, it is necessary to rewrite the original data, which complicates the operation. Along with this, there is a possibility that the power consumption at the time of reading is increased.

In the present embodiment, a partial cell 11 in which the channel portion 30 of the ferroelectric FET 12 and the resistor 13 are connected in parallel is constituted. The plurality of partial cells 11 are connected in series to form the memory cell 10. In each ferroelectric FET 12, on or off (LVt or HVt) binary is written. During the readout operation, the resistor connected in parallel to the ferroelectric FET 12 selected to be in the off-state determines the resistance of the entire memory cell 10. Therefore, the N-bit data stored in the memory cell 10 may be read as the resistance of the memory cell 10.

Thus, the ferroelectric FET 12 of each partial cell 11 serves as a switch for switching whether or not to select the resistor 13, and the data stored in the partial cell 11 is represented by the resistance level. Therefore, for example, even if there is some variation or the like in the characteristics of the ferroelectric FET 12, if it is possible to switch on/off, it is possible to properly perform the writing and reading of data. This may realize a stable memory function without being affected by variations in FET characteristics.

By using the ferroelectric film 15 as the gate dielectric film, a large on/off ratio (e.g., LVt/HVt ratio) may be ensured by spontaneous polarization. Thus, the allowable range of the read voltage Vr is widened, and it is possible to realize a stable readout operation or the like. Further, it is unnecessary to control the internal state of the ferroelectric film 15 in a stepwise manner, and it is unnecessary to check Vt for each bit. This may realize a high writing speed. Since the circuit for performing the confirmation process is also unnecessary, with suppressing power consumption, it is possible to achieve high integration by reducing the element area. As described above, by mounting the memory cell 10 according to the present embodiment, it is possible to realize an element having a nonvolatile memory function capable of stably storing data and achieving high integration.

In the present embodiment, the memory cell 10 has a chain cell structure in which the plurality of partial cells 11 are connected in series. Therefore, it is not necessary to connect the source line 4 and the bit line 5 to each of the partial cells 11, and it is possible to greatly reduce the element area. Since one source lines 4 and one number of bit lines 5 are connected to the memory cell 10, the parasitic capacitance is reduced and the capacitance of the data signal path may be reduced. Thus, operation with small power consumption is possible.

Since this configuration does not use a ferroelectric capacitor, an access transistor or the like is not required. Therefore, it is possible to configure the entire element compactly. As described above, the data stored in the memory cell 10, i.e., the partial cell 11, is maintained before and after reading. Since non-destructive reading of data may be performed in this manner, a simple readout operation may be performed, and power consumption required for reading may be sufficiently suppressed.

In the present embodiment, as described with reference to FIG. 4 and the like, it is possible to store multi-value data in the memory cell 10. For example, by making the resistance value of the resistor 13 different for each partial cell 11, the memory cell 10 capable of storing multi-value data is configured. In the present embodiment, the resistance value may be easily changed by changing the area of the resistor 13, as shown in FIG. 14. As a result, it is possible to implement n different kinds of resistances while suppressing the cost without increasing the number of processes, and it is possible to realize a low-cost multi-value memory or the like.

### Second Embodiment

The nonvolatile memory device according to the second embodiment of the present technology will be described. In the following description, descriptions of a configuration and an operation similar to those of the nonvolatile memory device 100 described in the embodiment above are omitted or simplified.

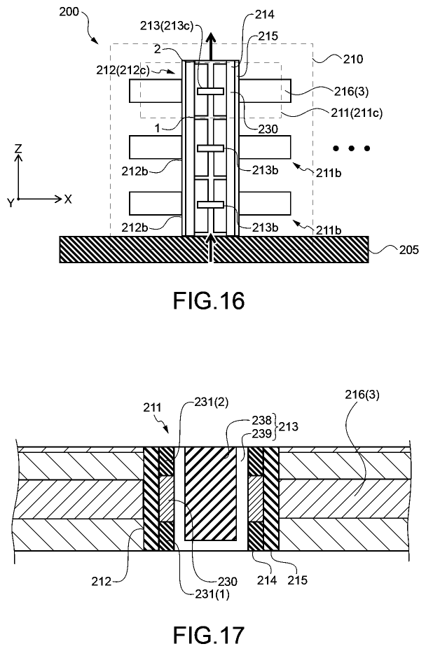

FIG. 16 is a schematic cross-sectional view showing a configuration example of a memory cell mounted in the nonvolatile memory device according to the second embodiment. In the present embodiment, the memory cell 210 of the nonvolatile memory device 200 is composed of a plurality of partial cells 211 stacked on each other. Specifically, the partial cells 211 constituting the memory cell 210 are three-dimensionally arranged along the stacking direction (thickness direction) on a predetermined board 205. As described above, by stacking the partial cells 211 in the thickness direction of the element and arranging them three-dimensionally, it is possible to form the memory cell 210 that realizes multi-value N bits in one footprint. As a result, it is possible to drastically reduce the element area and to efficiently lay out the nonvolatile memory device 200 having a large data capacity.

FIG. 17 is a schematic cross-sectional view showing a configuration example of the partial cell 211. The partial cell 211 has a ferroelectric FET 212 and a resistor 213. The ferroelectric

FET 212 has the cylindrical semiconductor film 214, a ferroelectric film 215 surrounding the semiconductor film 214, a source 1, a drain 2, and a gate 3. In the semiconductor film 214, the source 1 and the drain 2 are formed, between which the channel portion 230 serving as a conducting path (channel) is formed. Hereinafter, directions orthogonal to each other along the surface of the board 205 are defined as an X direction and a Y direction, and a stacking direction perpendicular to the surface of the board 205 is defined as a Z direction. In FIG. 16, the lateral direction in the figure is the X direction, the vertical direction is the Z direction.

In the ferroelectric FET 212, the cylindrical semiconductor film 214 is disposed along the Z-direction. The ferroelectric film 215 serving as a gate dielectric film is disposed so as to cover the entire circumference of the semiconductor film 214. Also on the outside of the ferroelectric film 215, the electrode film constituting the gate 3 is disposed so as to surround the entire periphery of the ferroelectric film 215. Contact portions 231 functioning as the source 1 or the drain 2 are formed below and above the cylindrical semiconductor film 214. A channel portion 230 is formed between the contact portions 231. Therefore, in the ferroelectric FET 212, the cylindrical contact portions 231 are formed above and below the cylindrical semiconductor film 214, and the cylindrical channel portion 230 is formed therebetween. Thus, the ferroelectric FET 212 has the cylindrical semiconductor film 214 extending along the stacking direction in which the channel portion 230 is formed.

Thus the ferroelectric FET 212 for controlling the conduction of the channel portion 230 in accordance with the voltage applied to the gate 3 is configured. In addition, HVt and LVt may be appropriately set in the ferroelectric FET 212 by using spontaneous polarization of the ferroelectric film 215. In the below description, the contact portions 231 provided below and above are described as the source 1 and the drain 2, respectively. In FIG. 16, the electrode representing the source 1 and drain 2 are schematically illustrated. Actually, as shown in FIG. 17, such an electrode is not formed.

The resistor 213 is disposed inside the cylindrical semiconductor film 214. As shown in FIG. 16, the resistor 213 is connected between the source 1 and the drain 2. Thus, the resistor 213 is connected in parallel with the channel portion 230 of the ferroelectric FET 212. Thus, the partial cell 211 is configured as a parallel circuit having a ferroelectric FET 212 for controlling the conduction of the channel portion 230 and a resistor 213 connected in parallel to the channel portion 230.

As shown in FIG. 17, the resistor 213 includes an electrode portion 238 and a resistor film 239. The resistor film 239 is a film formed by laminating a resistance material having a predetermined resistance value so as to cover the inner surface and the bottom surface of the semiconductor film 214. The electrode portion 238 is formed using an electrode material such as metal, and is filled in a space surrounded by the resistor film 239. As described above, the resistor 213 has a structure in which the electrode portion 238 is filled in the cylindrical resistor film 239 whose bottom surface is closed. Thus, the electrode portion 238 does not contact even when the partial cells 211 are stacked, and it is possible to properly maintain the resistance value. As will be described later, the resistance value of the resistor 213 may be appropriately set by controlling the film thickness of the resistor film 239.

The material of the resistor film 239 may be appropriately selected so that, for example, the resistor 213 has a desired resistance value. For example, a metal compound, a semiconductor film, a metal oxide film, an insulating film, or the like may be used as the resistor film 239. Alternatively, a combination of these materials may form the resistor film 239. The type and the like of the material of the resistor film 239 are not limited. As an electrode material of the electrode portion 238, for example, a metal compound such as titanium nitride (TiN) or tantalum nitride (TaN), or a low resistance metal such as titanium (Ti) or tungsten (W) is used. In addition, the type and the like of the material of the electrode portion 238 are not limited.

The memory cell 210 is configured by connecting the above-described partial cells 211 in series in the Z direction. Thus, in the memory cell 210, the contact portion 231 below the ferroelectric FET 212 disposed on the upper side (e.g., source 1), and the contact portion 231 above the ferroelectric FET 212 disposed on the lower side (e.g., drain 2) are connected. In other words, the ferroelectric FETs 212 stacked adjacently to the top and bottom have the contact portion 231 common to their interconnection.

FIG. 16 schematically shows a three-bit memory cell 210 including three partial cells 211a to 211c. The partial cell 211a has a ferroelectric FET 212a and resistor 213a and is formed on the board 205. The partial cell 211b includes a ferroelectric FET 212b and a resistor 213b, and is formed in an upper layer of the partial cell 211a. The partial cell 211c includes a ferroelectric FET 212c and a resistor 213c, and is formed in an upper layer of the partial cell 211b. The circuit diagram of the memory cell 210 shown in FIG. 16 is the same as the circuit diagram described with reference to FIG. 2.

A source line is connected to the source 1 of the partial cell 211a, and a bit line is connected to the drain 2 of the partial cell 211c. A word line is connected to the gate 3 of each partial cell 211 through a contact electrode or the like. The source line, the bit line, and the word line are appropriately formed using a wiring layer or the like (not shown). A memory cell array is constructed in which a plurality of memory cells 210 are connected to these wirings (source line, bit line, and word line) and represented by a circuit diagram as shown in FIG. 1.

For example, a predetermined voltage is applied between the source line and the bit line, and a current flows through the memory cell 210. In FIG. 16, a current flowing through the memory cell 210 is schematically illustrated using arrows. In this case, the ferroelectric FET 212 in which HVt is set in the memory cell 210 is in the off-state even if the read voltage Vr is applied. Without passing through the ferroelectric FET 212 of such an off-state, a current flows through the resistor 213.

At this time, the selection combination of the three ferroelectric FETs 212 (2³=8 types) determines the resistance of the memory cell 210. Therefore, a current corresponding to the eight resistance values of the memory cell 210 flows through the memory cell 210. This current is detected by a sense amplifier (not shown) or the like, and thereby data of three bits stored in the memory cell 210 may be read out.

The method of reading the data stored in the memory cell 210 is the same as the method described with reference to FIGS. 3 and 4. That is, data may be read out individually from each partial cell 211, or the entire multi-value data recorded in the memory cell 210 may read out.

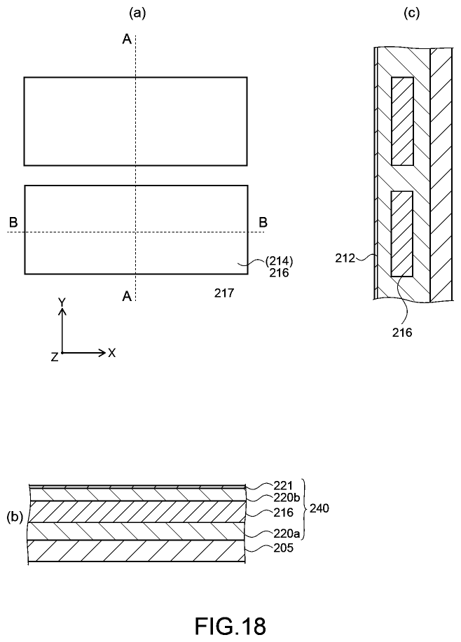

FIGS. 18 to 21 are plan views and cross-sectional views showing each step of the manufacturing method of the nonvolatile memory device 200. In each of FIGS. 18 to 21, a plan perspective view (a) of the board 205 (nonvolatile memory device 200) seen from the Z direction, a cross-sectional view at AA line (b), and a cross-sectional view at BB line (c), the lines being shown in the plan perspective view (a), are schematically illustrated. Note that the above-mentioned AA line is a line for cutting the memory cell 210 along the X direction, and the BB line is a line for cutting the memory cell 210 along the Y direction. Hereinafter, a manufacturing method of the nonvolatile memory device 200 will be described with reference to FIGS. 18 to 21.

In FIG. 18, a step of forming a gate electrode 216 serving as the gate 3 of the ferroelectric FET 212 is shown. For example, the gate electrode 216 is a wiring used as a word line. Specifically, an element layer 240 including a gate electrode 216 sandwiched between interlayer films 220 is formed on the board 205. As described below, the element layer 240 is a layer in which a lower interlayer film 220a, a gate electrode 216, an upper interlayer film 220b, and a boundary film 221 are deposited in this order. In the present embodiment, the interlayer film 220 (the lower interlayer film 220a and the upper interlayer film 220b) corresponds to an interlayer insulating film, and the gate electrode 216 corresponds to a gate electrode film.

First, the lower interlayer film 220a is deposited over the entire surface of the board 205. As the lower interlayer film 220a, an SiO₂ film is used, and the film thickness thereof is set to, for example, about 100 nm to 500 nm. The SiO₂ film is formed, for example, by the CVD method. Incidentally, the board 205 may be a Si board, or may be a board in which the wiring such as another CMOS circuit (W, TiN or the like) is formed. When a Si board is used, phosphorus or the like may be doped in advance.

Subsequently, the gate electrode 216 is formed over the entire surface of the lower interlayer film 220a. As the gate electrode 216, for example, a TiN film is used, and the film thickness thereof is set to, for example, about 100 nm. The TiN film is formed by, for example, the physical vapor deposition (PVD) method or the CVD method. Also, an Si-based (Poly-Si (polysilicon) or a-Si (amorphous silicon) or the like) film may be used instead of the TiN film. Further, other metallic materials, compound materials, and the like may be used. When the gate electrode 216 is deposited, the electrode pattern is patterned using a lithography method, and the gate electrode 216 is patterned by dry etching or the like. This forms a word line.

Subsequently, the upper interlayer film 220b is deposited over the entire surface of the surface on which the pattern of the gate electrode 216 is formed. As the upper interlayer film 220b, an SiO₂ film is used, and the film thickness thereof is set to, for example, about 100 nm to 500 nm. The SiO₂ film is formed, for example, by the CVD method. Thereafter, the upper interlayer film 220b is planarized by the CMP method. A boundary film 221 is deposited over the entire surface of the flattening surface. As the boundary film 221, an SiN film is used, and the film thickness thereof is set to, for example, 10 nm to 30 nm. The SiN film is formed by, for example, the CVD method. Thus, in the manufacturing process of the ferroelectric FET 212, the element layer 240 including the gate electrode 216 sandwiched between the interlayer films 220 is formed.

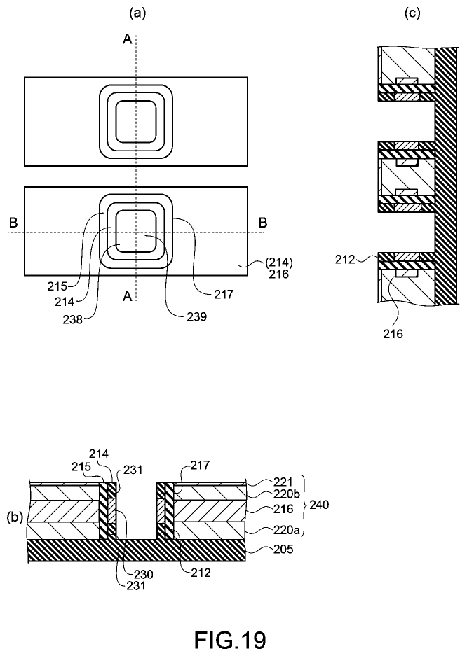

In FIG. 19, a step of forming the ferroelectric FET 212 is shown. Specifically, a hole 217 is formed in the element layer 240, and the ferroelectric film 215 and the semiconductor film 214 are formed in this order on the inner surface of the hole 217. Then the contact portion 231 serving as the source 1 or the drain 2 is formed on the semiconductor film 214.

First, a hole 217 is formed on the pattern (word line region) of the gate electrode 216 so as to reach the board 205 through the element layer 240. For example, using a lithographic method, a resist pattern having an open area corresponding to the hole 217 is formed. Using this resist pattern as a mask, the element layer 240 is etched until reaching the board 205. Thus, in the manufacturing process of the ferroelectric FET 212, the hole 217 penetrating the element layer 240 is formed.

Subsequently, the ferroelectric film 215 is formed on the inner surface of the hole 217. First, the ferroelectric film 215 is formed over the entire surface of the element layer 240 where the hole 217 is formed. As the ferroelectric film 215, for example, a hafnium oxide (HfOₓ) film is used. The the thickness of HfOₓ film is set to, for example, about 3 to 10 nm. The HfOₓ film is formed by, for example, the CVD method, the ALD (Atomic Layer Deposition) method, or the like. In addition, the ferroelectric film 215 may be formed using HfZrOₓ, ZrOₓ, PZT, SBT or the like. The ferroelectric film 215 may be doped with atomics such as La, Si, or Gd.

After forming the ferroelectric film 215, the rest ferroelectric film 215 is removed so that the ferroelectric film 215 remains on the inner surface of the hole 217. Here, the HfOₓ film is removed by the etch-back method to expose the bottom surface (board 205) of the hole 217. At this time, the HfOₓ film stacked on the surface of the element layer 240 is also removed. Thus, as shown in FIG. 19, a cylindrical gate dielectric film made of ferroelectric (ferroelectric film 215) is formed on the inner surface of the hole 217.

Subsequently, the semiconductor film 214 is formed on the inner surface of the cylindrical ferroelectric film 215. Silicon (Si) is used as the semiconductor film 214, and the film thickness is set to about 3 nm to 10 nm. The silicon film is deposited over the entire surface of the element layer 240 by, e.g., the CVD method. Incidentally, the silicon may be an a-Si, or may be a Poly-Si. The silicon film may be formed by epitaxial growth from the board 205.

After forming the semiconductor film 214 (Si), the rest semiconductor film 214 is removed so that the semiconductor film 214 remains on the inner surface of the ferroelectric film 215. Here, the Si film is removed by the etch-back method to expose the bottom surface (board 205) of the hole 217. At this time, the Si film laminated on the surface of the element layer 240 is also removed. Thus, as shown in FIG. 19, on the inner surface of the cylindrical ferroelectric film 215, the cylindrical semiconductor film 214 is formed. Thus, in the manufacturing process of the ferroelectric FET 212, on the inner surface of the hole 217, the gate dielectric film made of ferroelectric (ferroelectric film 215) and the semiconductor film 214 forming the channel portion 230 are formed in this order.

Subsequently, in the cylindrical semiconductor film 214, the contact portion 231 serving as the source 1 or the drain 2 is formed. For example, phosphorus (P) ions are implanted as the second conductivity type impurity into the element layer 240. At this time, the ion-injection concentration is set to, for example, about 1×10¹⁴/m² to 5×10¹⁵/cm². Further, the annealing treatment is performed by RTP (Rapid Thermal Processing) at annealing temperatures of 900° C. to 1000° C. for 30 seconds or less to activate the ion-implanted impurities (dopants). Thus, the contact portion 231 is formed above the semiconductor film 214 (the portion serving as a shoulder in cross section). At this time, phosphorus doped in the board 205 diffuses into the semiconductor film 214, and the contact portion 231 is also formed below the semiconductor film 214. In addition, the ferroelectric film 215 (HfOₓ film) is crystallized by the annealing process, and a high-quality ferroelectric material is formed.

Thus, as shown in FIGS. 19 (b) and (c), the contact portion 231 is formed above and below the cylindrical semiconductor film 214, and the channel portion 230 is formed therebetween. Note that it is also possible to dope the channel portion 230 with an impurity by oblique ion implantation. For example, ions such as boron (B) are implanted at an angle of 30 deg to 60 deg. At this time, the ion implantation concentration is set to, for example, about 1×10¹¹/cm² to 1×10¹³/cm². Thus, the impurity concentration of the channel portion 230 is adjusted, and it is possible to control the threshold voltage Vt of the ferroelectric FET 212.

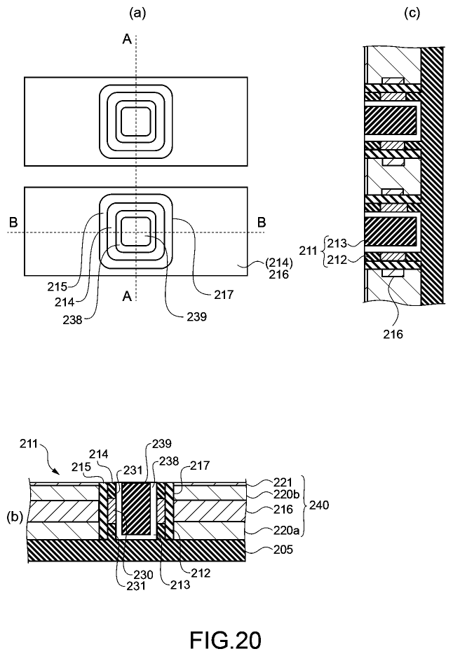

FIG. 20 shows a step of forming the resistor 213. Specifically, a resistor film 239 is formed on the inside of the cylindrical semiconductor film 214, and an electrode portion is formed on the inside of the resistor film 239.

First, the resistor film 239 is formed over the entire surface of the element layer 240. At this time, the resistor film 239 is formed so as to cover the inner surface and the bottom surface, from which the board 205 is exposed, of the semiconductor film 214. As the resistor film 239, an isolated film such as SiOₓ, AlOₓ, HfOₓ, ZrOₓ, and MgOₓ formed by using the CVD method, ALD method, or the like is used, and the film thickness is set to about 1 nm to 3 nm. The type or the like of the resistor film 239 is not limited. As described above, in the manufacturing process of the resistor 213, the resistor film 239 is formed so as to cover the inner surface and the bottom surface of the semiconductor film 214.

Subsequently, an electrode material serving as the electrode portion 238 is formed over the entire surface of the element layer 240. As an electrode material, for example, TiN formed using the CVD method, the ALD method, or the like is used, and a film thickness thereof is set to about 10 nm to 50 nm. The type of the electrode material is not limited. The film thickness of the electrode material may be appropriately set so that the inside of the resistor film 239 may be filled, for example. After the electrode material is formed, the electrode material and the resistor film 239 are polished by the CMP method. As a result, the electrode portion 238 filling the inside of the resistor film 239 is formed. As described above, in the manufacturing process of the resistor 213, the electrode portion 238 is filled in the space surrounded by the resistor film 239. Through the above steps, the partial cell 211 in which the channel portion 230 and the resistor 213 are connected in parallel is formed.

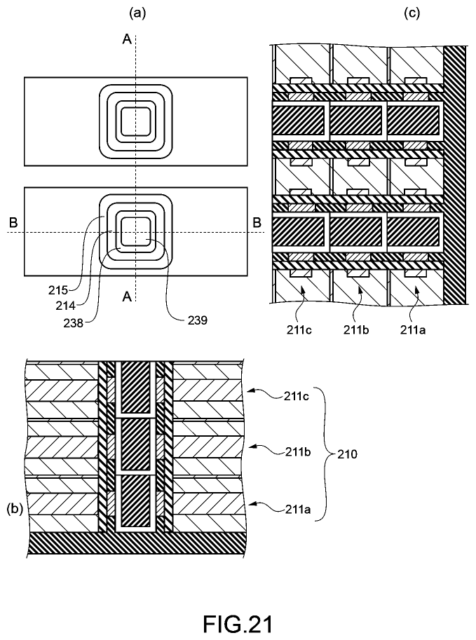

FIG. 21 shows a step of forming the memory cell 210 by stacking the partial cells 211. For example, by repeating the steps described with reference to FIGS. 18 to 20, it is possible to form a layered structure of the partial cells 211. In the example shown in FIG. 21, the second and third element layers 240 are formed on the element layer 240 formed in FIG. 20. As a result, it is possible to form a memory cell 210 having a three-bit structure in which three partial cells 211a to 211c are stacked. Incidentally, the wiring (source line, bit line, word line) connected to each memory cell 210 may be appropriately formed in accordance with the step of laminating the partial cells 211.

According to the above steps, the nonvolatile memory device 100 according to the present embodiment may be formed. Note that the above-mentioned materials, numerical values, and the like are examples, and may be appropriately changed in accordance with the configuration of the apparatus and the like.

Here, a method of setting the resistance value of the resistor 213 according to the present embodiment will be described. As shown in FIGS. 17 and 20, the resistor 213 is formed inside the cylindrical semiconductor film 214. In this case, by controlling the film thickness of the resistor film 239 in contact with the inner surface and the bottom surface of the semiconductor film 214, it is possible to set the resistance value of the resistor 213.

For example, the thickness of the resistor film 239 is set to the same value for each of the plurality of partial cells 211 included in the memory cell 210. Thus, the resistance value of each resistor 213 is equal to each other. Thus, by equalizing the resistance value of the resistor 213 for each partial cell 211, for example, it is possible to unify the configuration of the sense amplifier or the like due to the homogeneous level of the data signal, and it is possible to simplify the readout process. Such a configuration is implemented in a nonvolatile memory device 200 for performing the individual readout described with reference to FIG. 3 and the like.

Further, the thickness of the resistor film 239 may be set to a value different from each other for each of the plurality of partial cells 211 included in the memory cell 210. In this case, the resistance value of each resistor 213 is a different value from each other. Thus, by varying the resistance value of the resistor 213 for each partial cell 211, it is possible to represent the data value by the magnitude of the data signal. As a result, the memory cell 210 may store multi-value data and output a data signal representing the multi-value data. In this case, the data signal may be treated as an analog signal representing multi-value data. Such a configuration is implemented in a nonvolatile memory device 200 for performing the collective readout described with reference to FIG. 4 and the like.

As described above, in the present embodiment, the vertical memory cell 210 in which the partial cells 211 are stacked is configured. The memory cell 210 may be used to realize a plurality of bit cells (chain cell) shown in FIG. 2 and a memory cell structure shown in FIG. 1. In particular, the vertical memory cell 210 may form a plurality of bits of cells in the footprint of one cell. As a result, it is possible to greatly reduce the element area and sufficiently reduce the manufacturing cost and the like.

As described above, even in the vertical memory cell 210, n different resistance values may be easily realized by appropriately changing the film thickness of the resistor 213. This allows a multi-value memory capable of storing multi-value data to be formed into a single footprint. This may provide a low-cost multi-value memory or the like.

### Third Embodiment

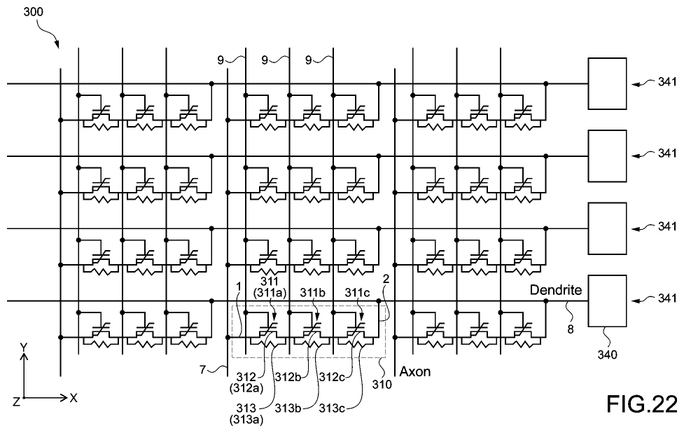

FIG. 22 is a circuit diagram showing a configuration example of a multiply-accumulate operation device according to the third embodiment. In the present embodiment, a multiply-accumulate operation device 300 using a nonvolatile memory element will be described. The multiply-accumulate operation device 300 is an analog operation device that executes a predetermined computing process including a multiply-accumulate computing. By using the multiply-accumulate operation device 300, it is possible to execute calculation processing according to a mathematical model such as a neural network, for example. In the present embodiment, the multiply-accumulate operation device 300 corresponds to a semiconductor element.

Here, the multiply-accumulate operation is, for example, an operation of adding a plurality of input values and a plurality of multiplied values obtained by multiplying the plurality of input values by weight values corresponding to the respective input values. Therefore, it may be said that the multiply-accumulate operation is a process of calculating the sum of each weight value. In the present embodiment, a case where the weight value is multi-value will be described mainly. That is, the multiply-accumulate operation device 300 may be said to be a device applicable to multi-value weights. First, with reference to FIG. 22, a description will be given of the basic circuit configuration of the multiply-accumulate operation device 300.

The multiply-accumulate operation device 300 includes a plurality of input lines 7, a plurality of output lines 8, a plurality of control lines 9, a plurality of multiplier cells 310, and a plurality of output units 340. In the multiply-accumulate operation device 300, a plurality of multiplier cells 310 are arranged in a matrix to form a cell array. Each multiplier cell 310 includes a plurality of partial cells 311. Multi-value weighting is realized by these partial cells 311. For example, by appropriately configuring the multiply-accumulate operation device 300, an operation device on which a machine learning model such as a neural network is mounted is configured. In the following, neuroscientific terminology may be used to describe the output line 8 as Dendrite and the input line 7 as Axon.

As shown in FIG. 22, the configuration of the multiply-accumulate operation device 300 except for the output unit 340 has the same circuit configuration as that of the nonvolatile memory devices 100 and 200 described in the above embodiment. For example, the input line 7, the output line 8, the control line 9, and the multiplier cell 310 of the multiply-accumulate operation device 300 may be associated with the source line, the bit line, the word line, and the memory cell in the nonvolatile memory devices 100 and 200. Accordingly, the multiply-accumulate operation device 300 may be configured in the same manner as a memory cell (see FIG. 5 and the like) configured by arranging partial cells in a planar manner, or a memory cell (see FIG. 16 and the like) configured by three-dimensionally stacking partial cells. In the present embodiment, the multiplier cell 310 corresponds to a cell block, and the partial cell 311 corresponds to a cell portion.

The input line 7 (Axon) is a wiring in which an input signal representing the input value is input. Here the input signal is, for example, an analog signal representing the input value by the width and the input timing of the pulse. The output line 8 is a wiring for transmitting an output signal output from each multiplier cell 310 to the output unit 340. The output signal is a signal representing the operation result (weight value) in the multiplier cell 310. The control line 9 is a wiring for transmitting a control signal for controlling the operation of the multiplier cell 310, respectively connected to a plurality of partial cells 311 included in the multiplier cell 310.

The multiplier cell 310 is configured with a plurality of partial cells 311 connected in series between the corresponding input lines 7 and output lines 8. The partial cell 311 also has ferroelectric FETs 312 and, resistors 313 connected in parallel to the channel portions of the ferroelectric FETs 312. The ferroelectric FET 312 controls the conduction of the channel portion in response to the voltage of the corresponding control line connected to the gate. Therefore, by appropriately operating the ferroelectric FET 312, on/off of the channel portion is switched, and it is possible to control the resistance of the partial cell 311. The resistor 313 is a resistor having a predetermined resistance value. In the present embodiment, the resistance value of the resistor 313 is set to a different value from each other for each partial cell 311 included in the multiplier cell 310.

In FIG. 22, the multiplier cell 310 having a three-bit structure including three partial cells 311a to 311c is used. The partial cell 311a includes a ferroelectric FET 312a and a resistor 313a, the partial cell 311b includes a ferroelectric FET 312b and a resistor 313b, and the partial cell 311c includes a ferroelectric FET 312c and a resistor 313c. To the source 1 of the ferroelectric FET 312a disposed on the left end of the multiplier cell 310, the corresponding input line 7 is connected, and to the drain 2 of the ferroelectric FET 312c disposed on the right end, the corresponding output line 8 is connected. The gates 3 of the ferroelectric FETs 312a to 312c are connected to corresponding control lines 9.

The multiplier cell 310 stores the weight value by a resistance level set for each of the plurality of partial cells 311. In the present embodiment, it is possible to store a multi-value weight for the multiplier cell 310. Specifically, by the combination of the resistance levels of the partial cells 311, the weight values of three or more kinds of multiple values are set. This may construct a neural network or the like in which the accuracy of inference or the like is greatly improved, as compared with a neural network configured by using, for example, two types of weight values (binary weights).

The basic operation of the multiplier cell 310 will now be described. When performing the multiply-accumulate operation, for all the partial cells 311 (ferroelectric FET 312) included in the multiplier cell 310, a read voltage Vr from the control line 9 is applied. This state is referred to as the operating state of the multiplier cell 310. The total resistance R_{T} of the multiplier cell 310 is a resistance corresponding to the resistance levels set in the partial cells 311. Using this total resistance R_{T}, a multi-value weight is set. For example, the value of the multi-value weight is a value proportional to, for example, the inverse of the total resistivity R_{T}, i.e., the total conductance in the multiplier cell 310. Note that the operation-state of the multiplier cell 310 corresponds to the state of the memory cell when the collective readout described with reference to FIG. 4 is performed.

In the multiply-accumulate operation, in the multiplier cell 310 of the operating state, an input signal having a pulse width corresponding to the input value is input. In this case, the current (charge) flows through the conducting path of the multiplier cell 310 by a time corresponding to the input value is output to the output line 8. The current value at this time is a value corresponding to the total resistance R_{T} which is the resistance value of the conducting path. Therefore, the total amount of charges output from the multiplier cell 310 to the output line 8 is a weight value of the input value (time) and the weight value (current value corresponding to the total resistance R_{T}). Thus, the multiplier cell 310 generates a charge corresponding to the weight value obtained by multiplying the weight value and the input value, and outputs the generated charge to the output line. As a result, a multiplication process of the multi-value weight and the input value is executed.

The output unit 340, based on the charges output to the output line 8 by the group of multiplier cells 310 connected to the common output line 8, outputs a multiply-accumulate signal representing the sum of the weight values in the group of multiplier cells 310. In the embodiment shown in FIG. 22, three multiplier cells 310 are connected to one output line 8 (Dendrite). These three multiplier cells 310 form a group of multiplier cells 310. The output unit 340 is provided for each output line 8.

For example, when the weight value is represented by the charge amount, the total amount of charges output from each connected multiplier cell 310 is detected, and a multiply-accumulate signal representing the sum of the weight values is generated based on the total amount of charges. This may perform a multiply-accumulate operation for calculating the sum of a plurality of weight values. The specific configuration of the output unit 340 is not limited. For example, by accumulating charges in a capacitor or the like (not shown), a circuit such as detecting the voltage of the capacitor is used as the output unit 340. Alternatively, the output unit 340 or the like connected to the pair of output lines 8 may be used. In this case, positive multiplication is performed by the group connected to one output line 8, and negative multiplication is performed by the group connected to the other output line 8. Then, the output unit 340 calculates a positive multiply-accumulate result and a negative multiply-accumulate result, and calculates a final multiply-accumulate result based on these multiply-accumulate results. For example, such a configuration is also possible.

Thus, in the present embodiment, the multiply-accumulate operation device 300 is configured by outputting the charge corresponding to the weight value from each multiplier cell 310 to the common output line 8. The multiply-accumulate operation device 300 includes a group of the multiplier cells 310 connected to the common output line 8 and the output unit 340, and the plurality of multiply-accumulate operation devices 341 capable of outputting a multiply-accumulate signal are configured. These multiply-accumulate operation devices are connected in parallel to the plurality of input lines 7 (Axon). As a result, a plurality of multiply-accumulate operations may be simultaneously performed on the set of input values input from each input line 7, and the operation speed may be greatly improved.

As described above, in the present embodiment, the partial cell 311 in which the channel portions of the ferroelectric FETs 312 and the resistors 313 are connected in parallel is configured, and the multiplier cell 310 is configured by connecting the plurality of partial cells 311 in series. The multiplier cell 310 performs multiplication of the multi-value weight and the input value. Since the multiplier cell 310 has a chain cell structure, the element area may be sufficiently reduced. By applying such a multiplier cell 310 to the apparatus for performing the multiply-accumulate operation of the neural network circuit, for example, as compared with the case of configuring the multiply-accumulate operation with elements such as a XNOR, with reducing the element area, it is possible to perform the operation with low power. This configuration is also capable of accommodating multi-value weights. This may realize a neural network or the like with high inference accuracy and reduced power consumption.

### Other Embodiments

The present technology is not limited to the embodiments described above, and may achieve various other embodiments.

In the above, the case of constituting a partial cell using ferroelectric FETs is explained. The present invention is not limited thereto, and other nonvolatile FETs or the like may be used. For example, a MOSFET type element with a floating gate may be used as the memory unit. In this case, the floating gate functions as a nonvolatile memory layer. Further, for example, a charge trap type nonvolatile FET including an ONO film or the like may be used. In this case, the ONO film in which charges are accumulated functions as a nonvolatile memory layer. In addition, a partial cell may be formed using any element of a MOSFET type having a nonvolatile memory function.

As a MOSFET type element constituting the partial cell, a MOSFET or the like in which the threshold voltage is adjusted in advance may be used. For example, a MOSFET having two different threshold voltages Vt may be formed by controlling the amount of implantation of an impurity by ion implantation. That is, the threshold voltage of MOSFET, for each of the plurality of partial cells, is set to either one of the first threshold voltage or the second threshold voltage different from each other. For example, the first threshold voltage is set to HVt, and the second threshold voltage is set to LVt. Therefore, the resistance level of each partial cell is set by the threshold voltage of a preset MOSFET. This combination of threshold voltages may represent the data. The first threshold voltage corresponds to the first value, and the second threshold voltage corresponds to the second value.

In this case, the data needs to be determined in advance, and may not be changed (programmed). That is, the memory cell is used as an OTP (One Time Programmable) memory. For example, when a ferroelectric FET or another nonvolatile FET is used, the number of rewrites (Enduramce) or data holding (Retention) is often limited. On the other hand, in the normal MOSFET, there is no limitation on the number of times of rewriting or data holding. In addition, since a writing circuit is unnecessary, cost may be reduced. It is also possible to reduce the power consumption without the necessary to apply a high voltage as in the ferroelectric FET and other nonvolatile FETs. Such a configuration is useful, for example, in implementing a trained neural network.

In the above description, an example has been described in which a memory element (a memory cell and a multiplier cell) for storing data using the resistance level of a partial cell is applied to a nonvolatile memory device or a multiply-accumulate operation device. The memory element according to the present technology may be utilized as an electrical fuse for switching the connection of a circuit. A resistor mounted on the memory element is a highly stable element, and its characteristic does not greatly fluctuate depending on the use conditions. Therefore, by using the memory element, it is possible to configure a highly reliable fuse circuit.

At least two of the features of the present technology described above may also be combined. In other words, various features described in the respective embodiments may be combined discretionarily regardless of the embodiments. Further, the various effects described above are not limitative but are merely illustrative, and other effects may be provided.

In the present disclosure, “same,” “equal,” “orthogonal,” and the like are concepts including “substantially the same,” “substantially equal,” “substantially t orthogonal,” and the like. For example, a state included in a predetermined range (e.g., ±10%) based on “completely the same,” “completely equal,” “completely orthogonal,” or the like is also included.

Note that the present technology may also take the following configurations.

(1) A semiconductor element, including:
a plurality of cell blocks
   configured by connecting a plurality of cell portions in series with each other, the plurality of cell portions each having a MOSFET for controlling conduction of a channel portion and a resistor connected in parallel to the channel portion, and
   configured to store data by a resistance level set for each of the plurality of cell portions.

(2) The semiconductor element according to the item (1), in which the resistance level is represented by a resistance value of the cell portion in a state where a predetermined voltage is applied to a gate of the MOSFET.

(3) The semiconductor element according to the item (1) or (2), in which
the MOSFET includes a nonvolatile memory layer, and causes the channel portion to conduct according to a condition of the memory layer, and
the resistance level is set according to a state of the memory layer.

(4) The semiconductor element according to the item (3), in which
the memory layer is a gate dielectric film made of ferroelectric.

(5) The semiconductor element according to the item (1) or (2), in which
a threshold voltage of the MOSFET of each of the plurality of cell portions is set to either a first value or a second value different from each other, and
the resistance level is set by a threshold voltage of the MOSFET.

(6) The semiconductor element according to any one of the items (1) to (5), in which
the cell block includes the plurality of cell portions formed on a same surface.

(7) The semiconductor element according to the item (6), in which
the resistor includes a pair of electrode films and a resistor film sandwiched between the pair of electrode films, and
an area of the resistor film is set to a different value for each of the plurality of cell portions included in the cell block.

(8) The semiconductor element according to any one of the items (1) to (5), in which
the cell block includes the plurality of cell portions stacked on each other.

(9) The semiconductor element according to the item (8), in which
the MOSFET includes a cylindrical semi-conductive film extending along a stacking direction and on which the channel portion is formed, and
the resistor includes a resistor film formed to cover an inner surface and a bottom surface of the semiconductor film, and an electrode portion filled in a space surrounded by the resistor film.

(10) The semiconductor element according to the item (9), in which
a thickness of the resistor film is set to a different value for each of the plurality of cell portions included in the cell block.

(11) The semiconductor element according to any one of the items (1) to (10), in which
a resistance value of the resistor is set to a different value for each of the plurality of cell portions included in the cell block.

(12) The semiconductor element according to the item (11), in which
the resistance value is set to a value obtained by multiplying a predetermined value by an integer power of 2.

(13) The semiconductor element according to any one of the items (1) to (10), in which
a resistance value of the resistor is set to a same value for each of the plurality of cell portions included in the cell block.

(14) The semiconductor element according to any one of the items (1) to (13), further including:
a plurality of source lines;
a plurality of bit lines; and
a plurality of word lines), in which
the MOSFET controls conduction of the channel portion in accordance with a voltage of the corresponding word line, and
each of the plurality of cell blocks is a nonvolatile memory cell
   connected between the corresponding source line and the corresponding bit line, and
   configured to store data according to the resistance level set for each of the plurality of cell portions.

(15) The semiconductor element according to any one of the items (1) to (13), further including:
a plurality of input lines in which an input signal representing an input value is input;
a plurality of output lines; and
a plurality of control lines), in which
the MOSFET controls conduction of the channel portion in accordance with a voltage of the corresponding control line, and
each of the plurality of cell blocks
   is a multiplier cell
      connected between the corresponding input line and the corresponding output line, and
      configured to store a weight value by the resistance level set for each of the plurality of cell portions, and generate a charge corresponding to a weight value obtained by multiplying the weight value and the input value, and
   constitutes a multiply-accumulate operation device by outputting a charge corresponding to the weight value to the common output line.

(16) A nonvolatile memory device, including:
a plurality of source lines;
a plurality of bit lines;
a plurality of word lines; and
a plurality of memory cells
   configured by connecting a plurality of cell portions in series between the corresponding source line and the corresponding bit line, the plurality of cell portions each having a MOSFET for controlling conduction of a channel portion in accordance with a voltage of the corresponding word line and a resistor connected in parallel to the channel portion, and
   configured to store data by a resistance level set for each of the plurality of cell portions.

(17) A multiply-accumulate operation device, including:
a plurality of input lines in which an input signal representing an input value is input;
a plurality of output lines;
a plurality of control lines;
a plurality of multiplier cells
   configured by connecting a plurality of cell portions in series between the corresponding input line and the corresponding output line, the plurality of cell portions each having a MOSFET for controlling conduction of a channel portion in accordance with a voltage of the corresponding control line and a resistor connected in parallel to the channel portion,
   configured to store a weight value by a resistance level set for each of the plurality of cell portions, and
   configured to generate a charge corresponding to a weight value obtained by multiplying the weight value and the input value; and
a plurality of output units configured to output a multiply-accumulate signal representing a sum of the weight values in a group of the multiplier cells based on the charge output to the output line by the group of the multiplier cells connected to the common output line.

(18) A method of manufacturing a semiconductor element including a plurality of cell blocks in which a plurality of cell portions are connected in series, including:
a forming process of the plurality of cell portions including
   forming a MOSFET for controlling conduction of a channel portion, and
   forming a resistor connected in parallel to the channel portion.

(19) The method of manufacturing a semiconductor element according to the item (18), further including:
a forming process of the MOSFET including
   forming an element layer including a gate electrode film sandwiched between interlayer insulating films,
   forming a hole penetrating the element layer, and
   forming, on an inner surface of the hole, a gate dielectric film made of ferroelectric and a semiconductor film forming the channel portion, in this order; and
a forming process of the resistor including
   forming a resistor film so as to cover an inner surface and a bottom surface of the semiconductor film, and
   filling an electrode portion in a space surrounded by the resistor film.

### REFERENCE SIGNS LIST

4 source line
5 bit line
6 word line
7 input line
8 output line
9 control line
10, 210 memory cell
11, 210 partial cell
12, 212 ferroelectric FET
13, 213 resistor
15, 215 ferroelectric film
16, 216 gate electrode
30, 230 channel portion
310 multiplier cell
311 partial cell
312 ferroelectric FET
313 resistor
340 output unit
100, 200 nonvolatile memory device
300 multiply-accumulate operation device

1. A semiconductor element, comprising:
a plurality of cell blocks
configured by connecting a plurality of cell portions in series with each other, the plurality of cell portions each having a MOSFET for controlling conduction of a channel portion and a resistor connected in parallel to the channel portion, and
configured to store data by a resistance level set for each of the plurality of cell portions.

2. The semiconductor element according to claim 1, wherein
the resistance level is represented by a resistance value of the cell portion in a state where a predetermined voltage is applied to a gate of the MOSFET.

3. The semiconductor element according to claim 1, wherein
the MOSFET includes a nonvolatile memory layer, and causes the channel portion to conduct according to a condition of the memory layer, and
the resistance level is set according to a state of the memory layer.

4. The semiconductor element according to claim 3, wherein
the memory layer is a gate dielectric film made of ferroelectric.

5. The semiconductor element according to claim 1, wherein
a threshold voltage of the MOSFET of each of the plurality of cell portions is set to either a first value or a second value different from each other, and
the resistance level is set by a threshold voltage of the MOSFET.

6. The semiconductor element according to claim 1, wherein
the cell block includes the plurality of cell portions formed on a same surface.

7. The semiconductor element according to claim 6, wherein
the resistor includes a pair of electrode films and a resistor film sandwiched between the pair of electrode films, and
an area of the resistor film is set to a different value for each of the plurality of cell portions included in the cell block.

8. The semiconductor element according to claim 1, wherein
the cell block includes the plurality of cell portions stacked on each other.

9. The semiconductor element according to claim 8, wherein
the MOSFET includes a cylindrical semi-conductive film extending along a stacking direction and on which the channel portion is formed, and
the resistor includes a resistor film formed to cover an inner surface and a bottom surface of the semiconductor film, and an electrode portion filled in a space surrounded by the resistor film.

10. The semiconductor element according to claim 9, wherein
a thickness of the resistor film is set to a different value for each of the plurality of cell portions included in the cell block.

11. The semiconductor element according to claim 1, wherein
a resistance value of the resistor is set to a different value for each of the plurality of cell portions included in the cell block.

12. The semiconductor element according to claim 11, wherein
the resistance value is set to a value obtained by multiplying a predetermined value by an integer power of 2.

13. The semiconductor element according to claim 1, wherein
a resistance value of the resistor is set to a same value for each of the plurality of cell portions included in the cell block.

14. The semiconductor element according to claim 1, further comprising:
a plurality of source lines;
a plurality of bit lines; and
a plurality of word lines, wherein
the MOSFET controls conduction of the channel portion in accordance with a voltage of the corresponding word line, and
each of the plurality of cell blocks is a nonvolatile memory cell
connected between the corresponding source line and the corresponding bit line, and
configured to store data according to the resistance level set for each of the plurality of cell portions.

15. The semiconductor element according to claim 1, further comprising:
a plurality of input lines in which an input signal representing an input value is input;
a plurality of output lines; and
a plurality of control lines, wherein
the MOSFET controls conduction of the channel portion in accordance with a voltage of the corresponding control line, and
each of the plurality of cell blocks
is a multiplier cell
connected between the corresponding input line and the corresponding output line, and
configured to store a weight value by the resistance level set for each of the plurality of cell portions, and generate a charge corresponding to a weight value obtained by multiplying the weight value and the input value, and
constitutes a multiply-accumulate operation device by outputting a charge corresponding to the weight value to the common output line.

16. A nonvolatile memory device, comprising:
a plurality of source lines;
a plurality of bit lines;
a plurality of word lines; and
a plurality of memory cells
configured by connecting a plurality of cell portions in series between the corresponding source line and the corresponding bit line, the plurality of cell portions each having a MOSFET for controlling conduction of a channel portion in accordance with a voltage of the corresponding word line and a resistor connected in parallel to the channel portion, and
configured to store data by a resistance level set for each of the plurality of cell portions.

17. A multiply-accumulate operation device, comprising:
a plurality of input lines in which an input signal representing an input value is input;
a plurality of output lines;
a plurality of control lines;
a plurality of multiplier cells
configured by connecting a plurality of cell portions in series between the corresponding input line and the corresponding output line, the plurality of cell portions each having a MOSFET for controlling conduction of a channel portion in accordance with a voltage of the corresponding control line and a resistor connected in parallel to the channel portion,
configured to store a weight value by a resistance level set for each of the plurality of cell portions, and
configured to generate a charge corresponding to a weight value obtained by multiplying the weight value and the input value; and
a plurality of output units configured to output a multiply-accumulate signal representing a sum of the weight values in a group of the multiplier cells based on the charge output to the output line by the group of the multiplier cells connected to the common output line.

18. A method of manufacturing a semiconductor element including a plurality of cell blocks in which a plurality of cell portions are connected in series, comprising:
a forming process of the plurality of cell portions including
forming a MOSFET for controlling conduction of a channel portion, and
forming a resistor connected in parallel to the channel portion.

19. The method of manufacturing a semiconductor element according to claim 18, further comprising:
a forming process of the MOSFET including
forming an element layer including a gate electrode film sandwiched between interlayer insulating films,
forming a hole penetrating the element layer, and
forming, on an inner surface of the hole, a gate dielectric film made of ferroelectric and a semiconductor film forming the channel portion, in this order; and
a forming process of the resistor including
forming a resistor film so as to cover an inner surface and a bottom surface of the semiconductor film, and
filling an electrode portion in a space surrounded by the resistor film.
